(19) United States
(12) Patent Application Publication
(10) Pub. No.: US 2026/0007031 A1
(43) Pub. Date: Jan. 1, 2026

(54) LIGHT EMITTING ELEMENT AND ELECTRONIC DEVICE INCLUDING THE SAME

(71) Applicant: Samsung Display Co., Ltd., Yongin-si (KR)

(72) Inventors: Hyoung cheol LIM, Yongin-si (KR); SEULONG KIM, Yongin-si (KR); JIMYOUNG YE, Yongin-si (KR); JAEHOON HWANG, Yongin-si (KR)

(73) Assignee: Samsung Display Co., Ltd., Yongin-si (KR)

(21) Appl. No.: 19/240,117

(22) Filed: Jun. 17, 2025

(30) Foreign Application Priority Data
Jun. 26, 2024 (KR) 10-2024-0083319
Jul. 8, 2024 (KR) 10-2024-0089714

(51) Int. Cl. H10K 59/38; H10K 50/12; H10K 50/16; H10K 50/17; H10K 50/18; H10K 85/40; H10K 85/60; H10K 102/00

(52) U.S. Cl. CPC H10K 59/38; H10K 50/12; H10K 50/16; H10K 50/171; H10K 50/181; H10K 85/40; H10K 85/626; H10K 85/633; H10K 85/636; H10K 85/654; H10K 85/6572; H10K 85/658; H10K 2102/351

(57) ABSTRACT

Embodiments provide a light emitting element and an electronic device that includes the light emitting element. The light emitting element includes a first electrode, a hole transport region disposed on the first electrode, a light emitting layer disposed on the hole transport region, an electron transport region disposed on the light emitting layer, a second electrode disposed on the electron transport region, and an auxiliary layer disposed between at least one of the hole transport region and the light emitting layer or the light emitting layer and the electron transport region. The auxiliary layer includes an anthracene compound represented by Formula 1, which is explained in the specification:

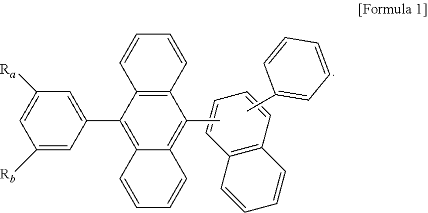

### CROSS-REFERENCE TO RELATED APPLICATION(S)

This application claims priority to and benefits of Korean Patent Application Nos. 10-2024-0083319 and 10-2024-0089714 under 35 U.S.C. § 119, respectively filed on Jun. 26, 2024 and Jul. 8, 2024, in the Korean Intellectual Property Office, the entire contents of which are incorporated herein by reference.

### BACKGROUND

### 1. Technical Field

The disclosure relates to a light emitting element including an auxiliary layer that is disposed adjacent to a light emitting layer and improves efficacy of the light emitting layer, and an electronic device including the light emitting element.

### 2. Description of the Related Art

Ongoing development continues for an organic electroluminescence display devices and the like as image display devices. The organic electroluminescence display devices are display devices including so-called self-emissive light emitting elements in which holes and electrons injected from first electrodes and second electrodes are recombined in light emitting layers so that light emitting materials of the light emitting layers emit light to achieve display.

Application of the light emitting elements to the display devices require improvement in luminous efficacy, improvement in lifespan, and the like, and to achieve these requirements. Thus continuous development is required for stack structures or materials of the light emitting elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element with improved luminous efficacy.

The disclosure also provides a display device including a light emitting element with improved luminous efficacy to have excellent display quality.

According to embodiments, a light emitting element may include a first electrode, a hole transport region disposed on the first electrode, a light emitting layer disposed on the hole transport region, an electron transport region disposed on the light emitting layer, a second electrode disposed on the electron transport region, and an auxiliary layer disposed between at least one of the hole transport region and the light emitting layer or the light emitting layer and the electron transport region, wherein the auxiliary layer may include an anthracene compound represented by Formula 1:

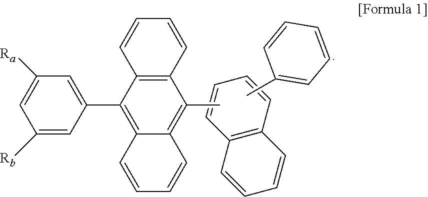

In Formula 1, Rₐ and R_{b} may each independently be a group represented by Formula 2.

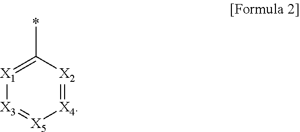

In Formula 2, X₁ to X₅ may each independently be N or CH.

In an embodiment, the auxiliary layer may be disposed directly between the light emitting layer and the electron transport region.

In an embodiment, the electron transport region may include a hole blocking layer disposed on the light emitting layer, an electron transport layer disposed on the hole blocking layer, and an electron injection layer disposed on the electron transport layer; and the auxiliary layer may be disposed directly between the light emitting layer and the hole blocking layer.

In an embodiment, the auxiliary layer may be disposed directly between the light emitting layer and the hole transport region.

In an embodiment, the anthracene compound may be represented by one of Formulae 1-1 to 1-6.

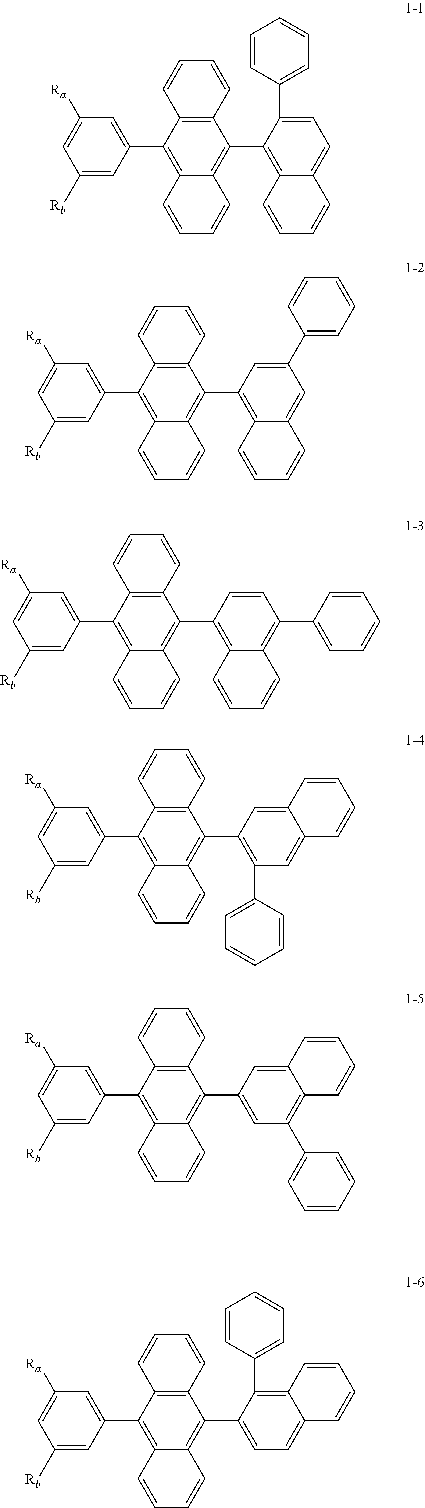

In in Formulae 1-1 to 1-6, Rₐ and R_{b} may each be the same as defined in Formula 1.

In an embodiment, the group represented by Formula 2 may be a group represented by one of Formulae 2a to 2h.

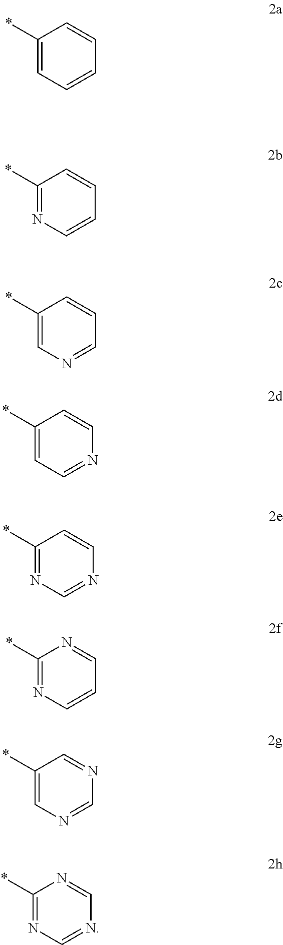

In an embodiment, the anthracene compound may be selected from Compound Group 1, which is explained below.

In an embodiment, the light emitting layer may have a thickness in a range of about 50 Å to about 200 Å; and the auxiliary layer may have a thickness in a range of about 10 Å to about 50 Å.

In an embodiment, the light emitting layer may include a host, and a blue dopant having a maximum emission peak in a range of about 400 nm to about 450 nm; and the auxiliary layer may not include a dopant but may include the anthracene compound.

According to embodiments, a light emitting element may include a first electrode, a second electrode facing the first electrode, and at least one light emitting structure disposed between the first electrode and the second electrode. The at least one light emitting structure may include a hole transport region, a light emitting layer disposed on the hole transport region, an electron transport region disposed on the light emitting layer, and an auxiliary layer disposed directly above and/or directly below the light emitting layer; and the auxiliary layer may include an anthracene compound represented by Formula 1.

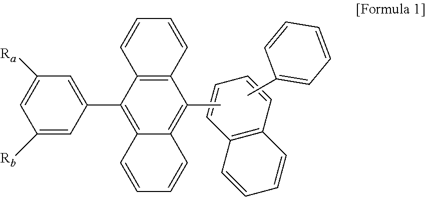

In Formula 1, Rₐ and R_{b} may each independently be a group represented by Formula 2.

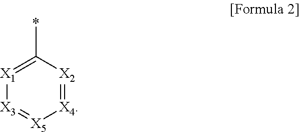

In Formula 2, X₁ to X₅ may each independently be N or CH.

In an embodiment, the light emitting element may include multiple light emitting structures; and the light emitting element may further include a charge generation layer between adjacent structures among the light emitting structures.

In an embodiment, the light emitting structures may include a first light emitting structure disposed on the first electrode and that emits blue light, a second light emitting structure disposed on the first light emitting structure and that emits blue light, a third light emitting structure disposed on the second light emitting structure and that emits blue light, and a fourth light emitting structure disposed on the third light emitting structure and that emits green light.

In an embodiment, the electron transport region may include a hole blocking layer, an electron transport layer, and an electron injection layer; the hole blocking layer, the electron transport layer, and the electron injection layer may be sequentially stacked in a thickness direction; and the auxiliary layer may be disposed directly between the light emitting layer and the hole blocking layer.

In an embodiment, in the light emitting element, the anthracene compound may be selected from Compound Group 1, which is explained below.

According to embodiments, an electronic device may include a display device providing images, and the display device may include a light emitting element that outputs a source light, and a light control panel disposed on the light emitting element; wherein the light control panel may transmit the source light or may convert a wavelength of the source light. The light emitting element may include a first electrode, a second electrode facing the first electrode, and at least one light emitting structure disposed between the first electrode and the second electrode. The at least one light emitting structure may include a hole transport region, a light emitting layer, an electron transport region, and an auxiliary layer disposed directly above or directly below the light emitting layer; and the auxiliary layer may include an anthracene compound represented by Formula 1.

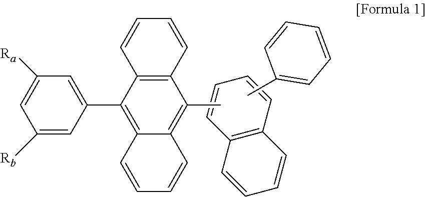

In Formula 1, Rₐ and R_{b} may each independently be a group represented by Formula 2.

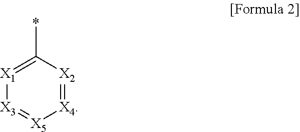

In Formula 2, X₁ to X₅ may each independently be N or CH.

In an embodiment, the display device may further include a first pixel area that emits red light, a second pixel area that emits green light, and a third pixel area that emits blue light, wherein the first to third pixel areas do not overlap each other in a plan view. The light control panel may include a light control layer including a quantum dot that converts a wavelength of the source light. The light control layer may include a first light control part disposed to correspond to the first pixel area and including a first quantum dot that converts the wavelength of the source light, a second light control part disposed to correspond to the second pixel area and including a second quantum dot that converts the wavelength of the source light, and a third light control part disposed to correspond to the third pixel area.

In an embodiment, the hole transport region may include a hole injection layer, a hole transport layer, and an electron blocking layer, wherein the hole injection layer, the hole transport layer and the electron blocking layer may be sequentially stacked in a thickness direction. The electron transport region may include a hole blocking layer, an electron transport layer, and an electron injection layer, wherein the hole blocking layer, the electron transport layer, and the electron injection layer may be sequentially stacked in the thickness direction, wherein the auxiliary layer may be disposed directly between the light emitting layer and the hole blocking layer.

In an embodiment, the light emitting element may include a host and a dopant, and the auxiliary layer may include the anthracene compound.

In an embodiment, the auxiliary layer may have a thickness in a range of about 10 Å to about 50 Å.

In an embodiment, in the electronic device, the anthracene compound may be selected from Compound Group 1, which is explained below.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will be more apparent by describing in detail embodiments thereof with reference to accompanying drawings, in which:

FIG. 1 is a schematic plan view of a display device according to an embodiment;

FIG. 2 is a schematic cross-sectional view of a display device according to an embodiment;

FIG. 3 is a schematic cross-sectional view of a light emitting element according to an embodiment;

FIG. 4 is a schematic cross-sectional view of a light emitting element according to an embodiment;

FIG. 5 is a schematic cross-sectional view of a light emitting element according to an embodiment;

FIG. 6 is a schematic cross-sectional view of a light emitting element according to an embodiment;

FIG. 7 is a schematic cross-sectional view of a light emitting element according to an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a light emitting element according to an embodiment;

FIG. 11A is a schematic energy level diagram in a light emitting element of the related art;

FIG. 11B is a schematic energy level diagram of a light emitting element according to an embodiment;

FIG. 12A is a schematic diagram of changes of energy levels in a light emitting element; and

FIG. 12B is a schematic diagram of changes of energy levels in a light emitting element according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (for example, the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification

In the specification, the terms “directly disposed” and “disposed directly” may each describe a condition that there is no additional layer, film, region, plate or the like between a part such as a layer, film, region, plate or the like and another part. For example, “directly disposed” may be interpreted such that two layers or two members are adjacently disposed, with no additional member, such as an adhesive member, between the two layers or two members.

In the specification, the term “substituted or unsubstituted” may describe a group that is substituted or unsubstituted with at least one substituent selected from the group consisting of a deuterium atom, a halogen atom, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents presented as an example above may itself be substituted or unsubstituted. For example, a biphenyl group may be interpreted as an aryl group or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring, or a substituted or unsubstituted heterocycle. A hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be linked to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. For example, two methyl groups in 4,5-dimethylphenanthrene may be interpreted as mutually “adjacent groups”.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 60, 1 to 30, 1 to 20, 1 to 15, 1 to 10, or 1 to 6. Examples of an alkyl group may include a methyl group, an ethyl group, an n-propyl group, an isopropyl group, an n-butyl group, a 5-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and the like, but embodiments are not limited thereto.

In embodiments, an alkyl group may be a cycloalkyl group (a cyclic alkyl group). The number of carbon atoms in a cycloalkyl group may be 3 to 60, 3 to 30, 3 to 20, or 3 to 10. Examples of an cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like, but embodiments are not limited thereto.

In the specification, an alkenyl group may be a hydrocarbon group including at least one carbon-carbon double bond in the middle or at an end of an alkyl group having 2 or more carbon atoms. An alkenyl group may be linear or branched. The number of carbon atoms is not particularly limited, and may be 2 to 60, 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, and the like, but embodiments are not limited thereto.

In the specification, an alkynyl group may be a hydrocarbon group that includes at least one carbon-carbon triple bond in the middle or at an end of an alkyl group having 2 or more carbon atoms. An alkynyl group may be linear or branched. The number of carbon atoms is not particularly limited, and may be 2 to 30, 2 to 20, or 2 to 10. Examples of an alkynyl group may include an ethynyl group, a propynyl group, and the like, but embodiments are not limited thereto.

In the specification, a hydrocarbon ring group may be any functional group or substituent derived from an aliphatic hydrocarbon ring. For example, the hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be a monocyclic aryl group or a polycyclic aryl group. The number of ring-forming carbon atoms in an aryl group may be 6 to 60, 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and the like, but embodiments are not limited thereto.

In the specification, a fluorenyl group may be substituted, and two substituents may be bonded to each other to form a spiro structure. Examples of a fluorenyl group may include the groups shown below. However, embodiments are not limited thereto.

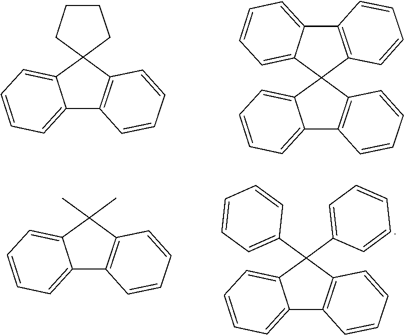

In the specification, a heterocyclic group may be any functional group or substituent derived from a ring that includes at least one of B, O, N, P, S, Si, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

When a heterocyclic group includes two or more heteroatoms, the two or more heteroatoms may be the same as or different from each other. The number of ring-forming carbon atoms in a heterocyclic group may be 2 to 60, 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and the like, but embodiments are not limited to thereto.

Examples of a heteroaryl group may include a thienyl group, a furyl group, a pyrrolyl group, an imidazolyl group, a pyridyl group, a bipyridinyl group, a pyrimidinyl group, a triazinyl, a triazolyl group, an acridinyl group, a pyridazinyl group, a pyazinyl group, a quinolyl group, a quinazolinyl group, a quinoxalinyl group, a phenoxazinyl group, a phthalazinyl group, a pyridopyrimidinyl group, a pyridopyrazinyl group, a pyrazinopyrazinyl group, an isoquinolinyl group, an indolyl group, a carbazolyl group, an N-arylcarbazolyl group, an N-(heteroarylcarbazolyl) group, an N-alkylcarbazolyl group, a benzoxazolyl group, a benzoimidazolyl group, a benzothiazolyl group, a benzocarbazolyl group, a benzothiophenyl group, a dibenzothiophenyl group, a thienothiophenyl group, a benzofuranyl group, a phenanthrolinyl group, a thiazolyl group, an isoxazolyl group, an oxazolyl group, an oxadiazolyl group, a thiadiazolyl group, a phenothiazinyl group, a dibenzosilolyl group, or a dibenzofuranyl group and the like, but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkyl silyl group or an aryl silyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and the like, but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

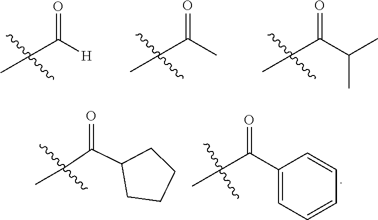

In the specification, the number of carbon atoms in a sulfinyl group or a sulfonyl group is not particularly limited, but may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkyl thio group or an aryl thio group. A thio group may bet a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and the like, but embodiments are not limited to thereto.

In the specification, an oxy group may be an oxygen atom that is bonded to an alkyl group or to an aryl group as defined above. An oxy group may be an alkoxy group or an aryl oxy group. An alkoxy group may be linear, branched or cyclic. The number of carbon atoms in an alkoxy group is not particularly limited, and may be, for example, 1 to 20, or 1 to 10.

Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and the like, but embodiments are not limited thereto.

In the specification, a boron group may be a boron atom that is bonded to an alkyl group or to aryl group as defined above. A boron group may include an alkyl boron group or an aryl boron group. Examples of a boron group may include a dimethyl boron group, a diethyl boron group, a t-butylmethyl boron group, a diphenyl boron group, a phenyl boron group, and the like, but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, and the like, but embodiments are not limited thereto.

In the specification, the above-described examples of an alkyl group may also apply to an alkylthio group, an alkyl sulfoxy group, an alkylaryl group, an alkylamino group, an alkyl boron group, an alkyl silyl group, and an alkyl amine group.

In the specification, the above-described examples of an aryl group may also apply to an aryloxy group, an arylthio group, an aryl sulfoxy group, an arylamino group, an aryl boron group, an aryl silyl group, and an aryl amine group.

In the specification, a direct linkage may be a single bond.

In the specification, the symbol [symbol] each represent a bond to a neighboring atom in a corresponding formula or moiety.

Hereinafter, a light emitting element according to an embodiment and a display device according to an embodiment will be described with reference to the accompanying drawings.

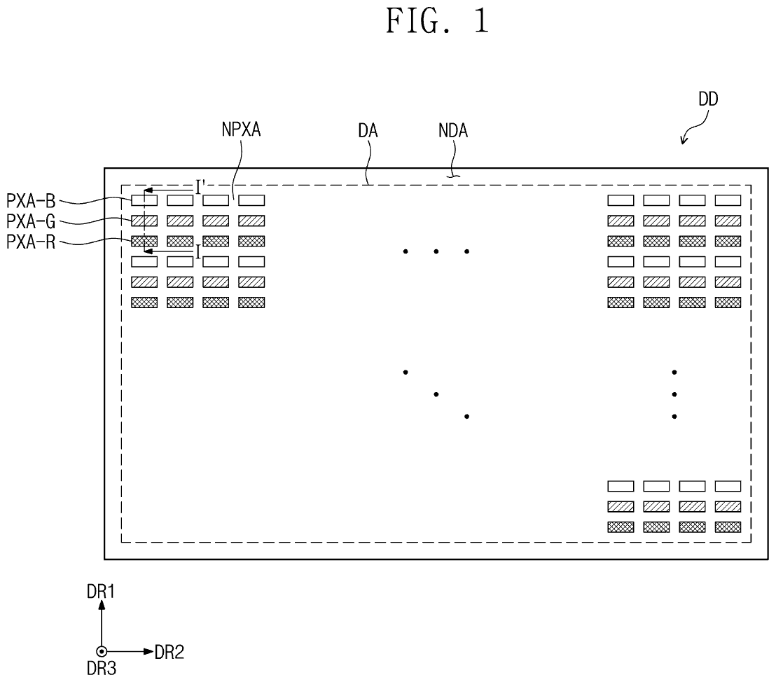

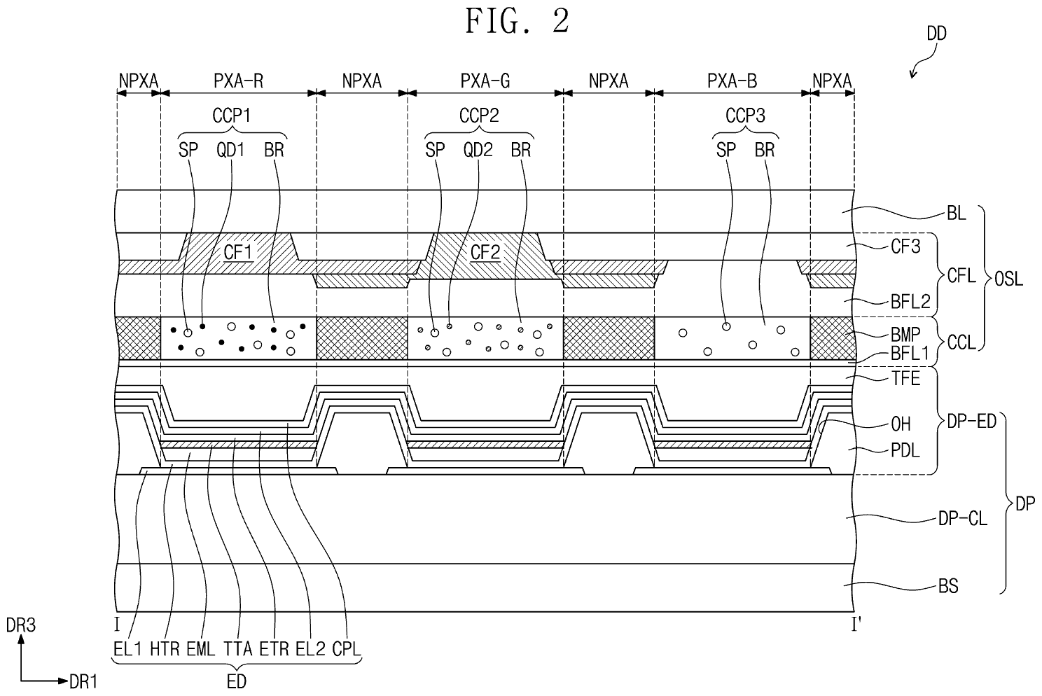

FIG. 1 is a schematic plan view of a display device DD according to an embodiment. FIG. 2 is a schematic cross-sectional view of a display device DD according to an embodiment. FIG. 2 is a schematic cross-sectional view of a portion of the display device DD taken along a virtual line I-I′ in FIG. 1.

The display device DD according to an embodiment may be a device that is activated in response to an electrical signal to display an image. Examples of a display device DD may include large, medium-sized, and small devices such as a television, a billboard, a monitor, a mobile phone, a tablet computer, a navigation device, and a game console. However, the aforementioned embodiments of the display device DD are presented only as examples, and embodiments are not limited to the particular examples listed above.

The display device DD may be rigid or flexible. In the specification, the term “flexible” indicates a property of being able to bend or fold. Examples of a flexible display device DD may include a curved device, a rollable device, and a foldable device.

According to an embodiment, an electronic device may include the display device DD and may provide images. The display device DD according to an embodiment may include a display module comprising the light-emitting element and an optical control panel. In an embodiment, an electronic device may further include at least one of a power module, a processor, and a memory in addition to the display module. The electronic device may be a video display device, a wearable device, or a vehicle device.

FIG. 1 and the following drawings show a first directional axis DR1, a second directional axis DR2, and a third directional axis DR3, and the directions indicated by the first, second, and third directional axes DR1, DR2, and DR3 as used herein are relative concepts and may be changed to other directions. The directions indicated by the first, second, and third directional axes DR1, DR2, and DR3 may be respectively referred to as first, second, and third directions DR1, DR2, and DR3, and may be designated by like reference numbers or symbols. In the specification, the first directional axis DR1 and the second directional axis DR2 may perpendicularly cross each other, and the third directional axis DR3 may be a normal direction to a plane defined by the first directional axis DR1 and the second directional axis DR2.

A thickness direction of the display device DD may be a direction that is parallel to the third directional axis DR3, which is a normal direction to a plane defined by the first directional axis DR1 and the second directional axis DR2. In the specification, a front surface (or top surface) and a rear surface (or bottom surface) of the members that constitute the display device DD may be defined based on the third directional axis DR3. The front surface (or top surface) and the rear surface (or bottom surface) of each of the members the constitute the display device DD may oppose each other in the third direction DR3, and a normal direction to each of the front surface and the rear surface may be substantially parallel to the third direction DR3. A spaced distance between the front surface and the rear surface, which is defined in the third direction DR3, may correspond to a thickness of the member.

In the specification, the term “in a plan view” may refer to a viewing perspective in the third direction DR3. In the specification, the term “cross-sectional view” may refer to a viewing perspective in the first direction DR1 and/or the second direction DR2. The, directions indicated by the first to third directions DR1, DR2, and DR3 are relative concepts and thus may be changed to other directions.

In an embodiment, the display device DD may include a display area DA and a non-display area NDA. Pixel areas PXA-R, PXA-G, and PXA-B are disposed in the display area DA. The non-display area NDA may surround the display area DA. However, embodiments are not limited thereto. For example, the non-display area NDA may be omitted or may be disposed on only a side of the display area DA.

Referring to FIGS. 1 and 2, the display device DD may include a first pixel area PXA-R, a second pixel area PXA-G, and a third pixel area PXA-B, which may emit light in different wavelength regions. The first pixel area, the second pixel area, and the third pixel area PXA-R, PXA-G, and PXA-B may be spaced apart without overlapping each other in a plan view. For example, in an embodiment, the first pixel area, the second pixel areas, and third pixel area may not overlap each other in a plan view.

In an embodiment, the first pixel area PXA-R may be a red light emitting area that emits red light, the second pixel area PXA-G may be a green light emitting area that emits green light, and the third pixel area PXA-B may be a blue light emitting area that emits blue light. However, embodiments are not limited thereto. For example, in addition to the first to third pixel areas PXA-R, PXA-G, and PXA-B, a pixel area which emits white light may be further included in the display area DA.

The pixel areas PXA-R, PXA-G, and PXA-B in the display device DD according to an embodiment may be arranged in a stripe configuration. Referring to FIG. 1, the first pixel areas PXA-R, the second pixel areas PXA-G, and the third pixel areas PXA-B may be respectively arranged along the second directional axis DR2. In another embodiment, the first pixel area PXA-R, the second pixel area PXA-G, and the third pixel area PXA-B may be arranged in this repeating order along the first directional axis DR1.

FIGS. 1 and 2 illustrate that the pixel areas PXA-R, PXA-G, and PXA-B all have a similar area. However, embodiments are not limited thereto, and the pixel areas PXA-R, PXA-G, and PXA-B may be different in size and/or shape from each other, according to a wavelength range of emitted light. The pixel areas PXA-R, PXA-G, and PXA-B may be areas in a plan view defined by the first directional axis DR1 and the second directional axis DR2.

An arrangement of the pixel areas PXA-R, PXA-G, and PXA-B is not limited to the embodiment illustrated in FIG. 1, and the order in which the first pixel area PXA-R, the second pixel area PXA-G, and the third pixel area PXA-B are arranged may be provided through various combinations according to the display quality characteristics that are required in the display device DD. For example, the pixel areas PXA-R, PXA-G, and PXA-B may be arranged in a pentile configuration (such as PenTile®) or in a diamond configuration (such as Diamond Pixel®).

In an embodiment, the pixel areas PXA-R, PXA-G, and PXA-B may be different in size from each other. For example, in an embodiment, an area of a second pixel area PXA-G that corresponds to a green light emitting area may be smaller than an area of a third pixel area PXA-B that corresponds to a blue light emitting area, but embodiments are not limited thereto.

Referring to FIG. 2, the display device DD according to an embodiment may include a display panel DP and a light control panel OSL disposed on the display panel DP. The display panel DP may include a base layer BS, a circuit layer DP-CL, and a display element layer DP-ED which may be stacked in sequence in the third directional DR3. The light control panel OSL may be disposed on the display element layer DP-ED. In the display device DD, the light control panel OSL may further include a color filter layer CFL and a base substrate BL.

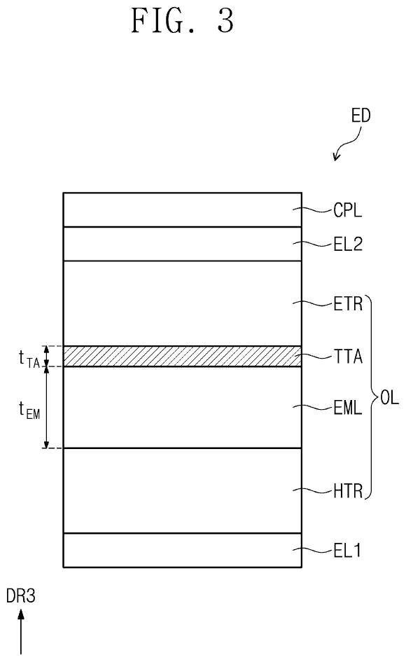

The display panel DP may include the base layer BS, the circuit layer DP-CL disposed on the base layer BS, and a display element layer DP-ED. The display element layer DP-ED may include a light emitting element ED. In an embodiment, the light emitting element ED may have a light emitting element structure according to an embodiment to be described later with reference to FIGS. 3 to 7.

In the display panel DP, the base layer BS may provide a base surface on which a component included in the circuit layer DP-CL is disposed. In an embodiment, the base layer BS may be a glass substrate, a metal substrate, a polymer substrate, or the like. However, embodiments are not limited thereto, and the base layer BS may include an inorganic layer, a functional layer, or a composite material layer.

The base layer BS may have a multilayer structure. For example, the base layer BS may have a three-layer structure including a polymer resin layer, an adhesive layer, and a polymer resin layer. In an embodiment, the polymer resin layer may include a polyimide-based resin. The polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the specification, a resin that is described as “a-based” may refer to a resin that is derived from a monomer that includes “a” as a functional group.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor each for driving the light emitting element ED of the display element layer DP-ED.

The display element layer DP-ED may include the light emitting element ED. In an embodiment, the light emitting element ED may generate a source light. In an embodiment, the source light provided by the light emitting element ED may be light in a blue wavelength region. However, embodiments are not limited thereto. In an embodiment, the light emitting element ED may include, as the source light, light in the red wavelength region and light in a green wavelength region, or the light emitting element ED may provide white light.

The light emitting element ED may include a first electrode EL1, a hole transport region HTR, a light emitting layer EML, an electron transport region ETR, and a second electrode EL2, which may be stacked in a thickness direction that is parallel to the third direction DR3. In an embodiment, the light emitting element ED may include an auxiliary layer TTA disposed adjacent to the light emitting layer EML. In an embodiment, the light emitting layer EML may be directly disposed on the auxiliary layer TTA. The light emitting element ED according to an embodiment may further include a capping layer CPL disposed on the second electrode EL2. The auxiliary layer TTA included in the light emitting element ED according to an embodiment may be disposed adjacent to the light emitting layer EML, thereby increasing efficacy of light emitted from the light emitting layer EML.

The light emitting element ED included in the display device DD according to an embodiment illustrated in FIG. 2 may provide a source light to the light control panel OSL disposed on the display panel DP. For example, in the display device DD according to an embodiment, the light emitting element ED may provide a first light as a source light to the light control panel OSL, and the light control panel OSL may transmit the source light or may convert a wavelength of the source light. The auxiliary layer TTA according to an embodiment and the light emitting element ED according to an embodiment that includes the auxiliary layer TTA will be described later in further detail.

The display element layer DP-ED may include a pixel defining film PDL. An opening OH may be defined in the pixel defining film PDL. The opening OH may expose at least a portion of the first electrode EL1. In an embodiment, the pixel areas PXA-R, PXA-G, and PXA-B may be defined by the opening OH.

In an embodiment, the pixel defining film PDL may be an organic layer. The pixel defining film PDL may be made of a polymer resin. For example, the pixel defining film PDL may include a polyacrylate-based resin or a polyimide-based resin. In another embodiment, the pixel defining film PDL may further include an inorganic substance in addition to the polymer resin. The pixel defining film PDL may include a light absorbing material, or may include a black pigment or a black dye. The pixel defining film PDL including the black pigment or the black dye may be a black pixel defining film. When the pixel defining film PDL is formed, carbon black or the like may be used as the black pigment or the black dye, but embodiments are not limited thereto.

The pixel defining film PDL may include an inorganic material. For example, the pixel defining film PDL may include an inorganic material such as silicon nitride (SiNₓ), silicon oxide (SiOₓ), or silicon oxynitride (SiOₓN_{y}).

The display element layer DP-ED may include an encapsulation layer TFE that protects the light emitting element ED. The encapsulation layer TFE may cover the display element layer DP-ED. The encapsulation layer TFE may be disposed on the light emitting element ED and may fill the openings OH. The encapsulation layer TFE may be directly provided on the light emitting element ED in a continuous process.

The encapsulation layer TFE may include an organic material or an inorganic material. The encapsulation layer TFE may have a single-layered structure or a multi-layered structure. The encapsulation layer TFE according to an embodiment may include at least one inorganic film (hereinafter referred to as an inorganic encapsulation film). In an embodiment, the encapsulation layer TFE may include at least one organic film (hereinafter referred to as an organic encapsulation film) and at least one inorganic encapsulation film. The encapsulation layer TFE may have a multilayer structure in which an inorganic film/an organic film are repeated.

The inorganic encapsulation film may protect the display element layer DP-ED from moisture and/or oxygen, and the organic encapsulation film may protect the display element layer DP-ED from foreign matter such as dust particles. The inorganic encapsulation film may include a silicon nitride, a silicon oxynitride, a silicon oxide, a titanium oxide, an aluminum oxide, or the like, but embodiments are not limited thereto. The organic encapsulation film may include an acryl-based compound, an epoxy-based compound, or the like. The organic encapsulation film may include a photopolymerizable organic material but embodiments are not limited thereto.

The display device DD according to an embodiment may include the light control panel OSL disposed on the display panel DP. The light control panel OSL may include a light control layer CCL including a photoconversion material. The photoconversion material may be a quantum dot, a phosphor, or the like. The photoconversion material may convert a wavelength of received light and may emit light having the converted wavelength. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 2, a divided pattern BMP may be disposed between the light control parts CCP1, CCP2, and CCP3 spaced apart from each other, but embodiments are not limited thereto. The divided pattern BMP shown in FIG. 2 does not overlap the light control parts CCP1, CCP2, and CCP3, but an edge of each of the light control parts CCP1, CCP2, and CCP3 may overlap at least a portion of the divided pattern BMP.

The light control layer CCL may include a first light control part CCP1 including a first quantum dot QD1 that converts first color light provided from the light emitting element ED into second color light, a second light control part CCP2 including a second quantum dot QD2 that converts the first color light into third color light, and a third light control part CCP3 that transmits the first color light.

In an embodiment, the first light control part CCP1 may provide red light that is the second color light, and the second light control part CCP2 may provide green light that is the third color light. The third light control part CCP3 may transmit and may provide the blue light that is the first color light provided from the light emitting element ED. For example, the first quantum dot QD1 may be a red quantum dot, and the second quantum dot QD2 may be a green quantum dot.

In the specification, the quantum dots QD1 and QD2 may be crystals of a semiconductor compound. The quantum dot may emit light having various emission wavelengths according to a size of the crystal. The quantum dot may emit light having various emission wavelengths by adjusting a ratio of elements in the semiconductor compound.

A diameter of the quantum dot may be, for example, in a range of about 1 nm to about 10 nm. The quantum dot may be synthesized through a wet chemical process, an organic metal chemical vapor deposition process, a molecular beam epitaxy process, or the like.

Among the quantum dot preparation processes, the wet chemical process is a method that includes mixing an organic solvent and a precursor material and growing quantum dot particle crystals. When the quantum dot particle crystals grow, the organic solvent may serve as a dispersant that is naturally coordinated on surfaces of the quantum dot crystals, and may control the growth of the particle crystals. Thus, in the wet chemical process, the growth of quantum dot particles may be controlled through a process that is more readily performed and at lower costs than a vapor deposition process such as metal organic chemical vapor deposition (MOCVD) or molecular beam epitaxy (MBE).

A quantum dot may include a Group II-VI compound, a Group III-V compound, a Group III-VI compound, a Group I-II-VI compound, a Group IV-VI compound, a Group II-IV-V compound, a Group IV element, a Group IV compound, or any combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof. In an embodiment, a Group II-VI semiconductor compound may further include a Group I metal and/or a Group IV element.

Examples of a Group I-II-VI compound may include CuSnS and CuZnS.

Examples of a Group II-IV-VI compound may include ZnSnS and the like.

Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group I-III-VI compound may include: a ternary compound such as AgInS, AgInS₂, CuInS, CuInS₂, AgGaS₂, CuGaS₂ CuGaO₂, AgGaO₂, AgAlO₂, and a mixture thereof; a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP and the like.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, and CdGeP₂, and a mixture thereof.

Examples of a Group IV element may include Si, Ge, and a mixture thereof. Examples of a Group IV compound may include a binary compound such as SiC, SiGe, and a mixture thereof.

Each of elements included in a compound such as a binary compound, a ternary compound, or a quaternary compound, may be present in a particle at a uniform concentration or at a non-uniform concentration. For example, a formula may indicate elements that are included in a quantum dot compound, but a ratio of the elements in the compound may vary.

In an embodiment, a quantum dot may have a core/shell structure in which a quantum dot surrounds another quantum dot. In the core-shell structure, the quantum dot may have a concentration gradient in which the concentration of an element that is present in the shell gradually decreases toward the core.

In embodiments, a quantum dot may have a core-shell structure that includes a nanocrystal core and a shell surrounding the core. The shell of the quantum dot may serve as a protective layer for preventing chemical modification of the core to maintain semiconductor characteristics, and/or may serve as a charging layer for imparting electrophoretic characteristics to the quantum dot. The shell may have a single-layer structure or a multilayer structure. The shell of the quantum dot may include, for example, a metal oxide, a nonmetal oxide, a semiconductor compound, or any combination thereof.

Examples of a metal oxide or a nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments are not limited thereto.

A quantum dot may have a full width at half maximum (FWHM) of an emission wavelength spectrum less than or equal to about 45 nm. For example, the quantum dot may have an FWHM of an emission wavelength spectrum less than or equal to about 40 nm. For example, the quantum dot may have an FWHM of an emission wavelength spectrum less than or equal to about 30 nm. In any of these ranges, color purity or color reproducibility may be improved. Light emitted through such quantum dots may be emitted in all directions so that a wide viewing angle may be improved.

The form of the quantum dot may be any form commonly used in the art, but embodiments are not limited thereto. For example, a quantum dot may have a spherical form, a pyramidal form, a multi-armed form, or a cubic form, or the nanoparticles may be in the form of nanoparticles, nanotubes, nanowires, nanofibers, nanoplate particles, or the like.

In a quantum dot, an energy band gap may be adjusted by adjusting a size of the quantum dot or adjusting a ratio of elements in a quantum dot compound, and thus light having various wavelength bands may be obtained in the quantum dot light emitting layer. Thus, a light emitting element that emits light having several wavelengths may be achieved by using the quantum dots (having different sizes or having different ratios of elements in a quantum dot compound) as described above. A size of the quantum dot or a ratio of elements in the quantum dot compound may be selectively adjusted so as to emit red, green and/or blue light. In an embodiment, the quantum dots may be configured so as to emit white light by combining light having various colors of light.

In an embodiment, as a particle size of the quantum dot is decreased, the quantum dot may emit light having a shorter-wavelength range. For example, in the quantum dots having a same core, a particle size of the quantum dot emitting green light may be less than a particle size of the quantum dot emitting red light. For another example, in the quantum dots having a same core, a particle size of the quantum dot emitting blue light may be less than a particle size of the quantum dot emitting the green light. However, embodiments are not limited thereto, and, even in the quantum dots having the same core, the particle sizes may be adjusted according to a material constituting the shell, a shell thickness, and the like.

In a case in which quantum dots have various emissive colors such as blue, red, and green, the quantum dots having different emissive colors may be different from each other in terms of their core materials.

The first light control part CCP1 may correspond to the first pixel area PXA-R, the second light control part CCP2 may correspond to the second pixel area PXA-G, and the third light control part CCP3 may correspond to the third pixel area PXA-B.

In an embodiment, the first light control part CCP1 may be referred to as a red light control part, the second light control part CCP2 may be referred to as a green light control part, and the third light control part CCP3 may be referred to as a blue light control part.

The first light control part CCP1, the second light control part CCP2, and the third light control part CCP3 may each include a base resin part BR. The first light control part CCP1, the second light control part CCP2, and the third light control part CCP3 may each further include a scatterer SP. In the first light control part CCP1, the first quantum dots QD1 and the scatterer SP may be dispersed and disposed in the base resin part BR, and in the second light control part CCP2, the second quantum dots QD2 and the scatterer SP may be dispersed and disposed in the base resin part BR. In the third light control part CCP3, the scatterer SP may be dispersed and disposed in the base resin part BR.

In an embodiment, the third light control part CCP3 may not include a quantum dot. However, embodiments are not limited thereto, and the third light control part CCP3 may further include a quantum dot that converts light into light having different wavelength regions from the first and second light control parts.

In an embodiment, the scatterer SP may uniformly scatter and emit the incident light on the light control parts CCP1, CCP2, and CCP3. The scatterer SP may scatter and emit the source light, or scatter and emit light wavelength-converted from the source light.

The scatterer SP may have a spherical shape having a diameter between tens of nanometers and hundreds of nanometers. For example, in an embodiment, the scatterer SP may have a diameter of about 50 nm to about 300 nm. For another example, in an embodiment, the diameter of the scatterer SP may be about 200 nm.

The scatterer SP may be an inorganic particle. For example, the scatterer SP may include TiO₂, BaTiO₃, ZnO, ZnS, Al₂O₃, SiO₂, or hollow silica.

The base resin part BR, which is a medium in which the quantum dots QD1 and QD2 and the scatterer SP are dispersed, may include various compositions which may be referred to as binders. For example, the base resin part BR may be an acrylate-based resin part, a urethane-based resin part, a silicon-based resin part, an epoxy-based resin part, or the like. All the base resin parts BR included in the first to third light control parts CCP1, CCP2, and CCP3 may be the same, or a base resin part in at least one of the light control parts may be different from base resin parts in the other light control parts.

The light control layer CCL may include a barrier layer BFL1. The barrier layer BFL1 may prevent permeation of moisture and/or oxygen (hereinafter referred to as “moisture/oxygen”). The barrier layer BFL1 may be disposed on the light control parts CCP1, CCP2, and CCP3 to prevent the light control parts CCP1, CCP2, and CCP3 from being exposed from moisture/oxygen. The barrier layer BFL1 may cover the light control parts CCP1, CCP2, and CCP3.

The light control panel OSL may further include a color filter layer CFL. The color filter layer CFL may be disposed on the light control layer CCL. The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymer photosensitive resin and a pigment or a dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or a dye. The third filter CF3 may include a polymer photosensitive resin but may not include a pigment or a dye. The third filter CF3 may be transparent. The third filter CF3 may be made of transparent photosensitive resin.

In an embodiment, the first filter CF1 and second filter CF2 may be yellow filters. The first filter CF1 and second filter CF2 may be provided in a body without being divided.

Although not illustrated in the drawings, the color filter layer CFL may further include a light blocking part (not illustrated). The light blocking part (not illustrated) may be a black matrix. The light blocking part (not illustrated) may include an organic light blocking material or an inorganic light blocking material each including a black pigment or a black dye. The light blocking part (not illustrated) may prevent light leakage, and may define a boundary between adjacent filters CF1, CF2, and CF3. In an embodiment, the light blocking part may be a blue filter.

The first to third filters CF1, CF2, and CF3 may be disposed to respectively correspond to the first pixel area PXA-R, the second pixel area PXA-G, and the third pixel area PXA-B.

The color filter layer CFL may further include a barrier layer BFL2. The barrier layer BFL2 may be disposed between the light control layer CCL and the filters CF1, CF2, and CF3.

The barrier layers BFL1 and BFL2 may each independently include at least one inorganic layer. For example, the barrier layers BFL1 and BFL2 may include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, and a silicon oxynitride, or a metal thin film having light transmittance and the like. The barrier layers BFL1 and BFL2 may each independently further include an organic film. The barrier layers BFL1 and BFL2 may each include a single layer or multiple layers.

The base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, or the like. However, embodiments are not limited thereto, and the base substrate BL may be an inorganic layer, an organic layer, or a composite material layer. Although not shown in the drawings, in an embodiment, the base substrate BL may be omitted.

FIGS. 3 to 7 are each a schematic cross-sectional view of a light emitting element according to an embodiment. The light emitting elements ED, ED-a, ED-b, ED-c, and ED-d according to embodiments may each include a first electrode EL1, a second electrode EL2 facing the first electrode EL1, and at least one light emitting structure OL, OL-1, or OL-2 disposed between the first electrode EL1 and the second electrode EL2. The light emitting structures OL, OL-1, and OL-2 may each include a hole transport region HTR, a light emitting layer EML, and an electron transport region ETR, which may be stacked in sequence, and an auxiliary layer TTA, TTA-T, or TTA-B disposed adjacent to the light emitting layer EML. The light emitting elements ED, ED-a, ED-b, ED-c, and ED-d according to embodiments may each include a capping layer CPL disposed on the second electrode EL2.

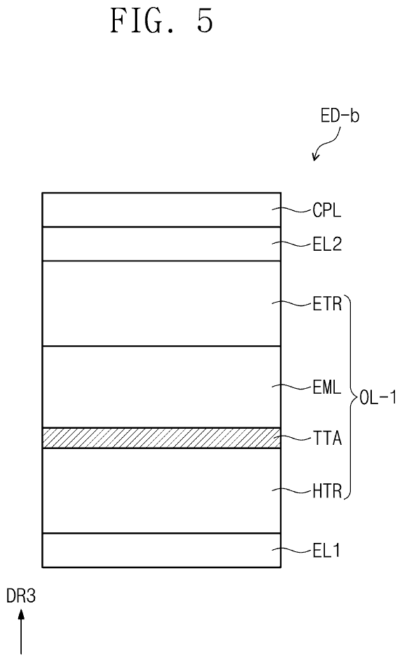

Referring to FIGS. 3 and 5, the light emitting elements ED and ED-b according to an embodiment may each include the auxiliary layer TTA directly disposed on the light emitting layer EML. In the light emitting element ED according to an embodiment illustrated in FIG. 3, the auxiliary layer TTA may be directly disposed on (e.g., directly disposed above) the light emitting layer EML, and in the light emitting element ED-b according to an embodiment illustrated in FIG. 5, the auxiliary layer TTA may be directly disposed below the light emitting layer EML.

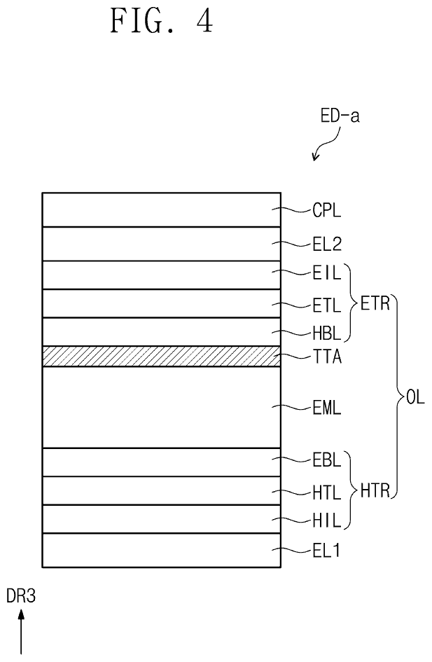

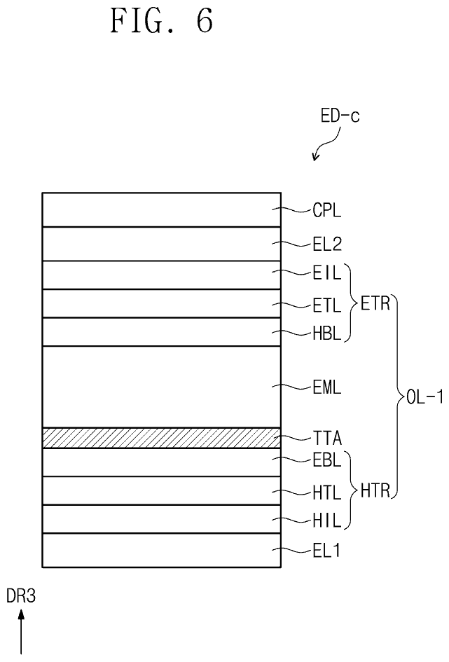

The light emitting element ED-a according to an embodiment illustrated in FIG. 4 and the light emitting element ED-c according to an embodiment illustrated in FIG. 6 are different such that the hole transport region HTR and the electron transport region ETR each include multiple layers, in comparison to the light emitting element ED illustrated in FIG. 3 and the light emitting element ED-b illustrated in FIG. 5. In the light emitting elements ED-a and ED-c according to embodiments illustrated in FIGS. 4 and 6, the hole transport region HTR may include a hole injection layer HIL, a hole transport layer HTL, and an electron blocking layer EBL, which are stacked in that order. In the light emitting elements ED-a and ED-c according to embodiments illustrated in FIGS. 4 and 6, the electron transport region ETR may include a hole blocking layer HBL, an electron transport layer ETL, and an electron injection layer EIL, which are stacked in that order. In the light emitting element ED-a illustrated in FIG. 4, the auxiliary layer TTA may be directly disposed between the light emitting layer EML and the hole blocking layer HBL, and in the light emitting element ED-c illustrated in FIG. 6, the auxiliary layer TTA may be directly disposed between the light emitting layer EML and the electron blocking layer EBL.

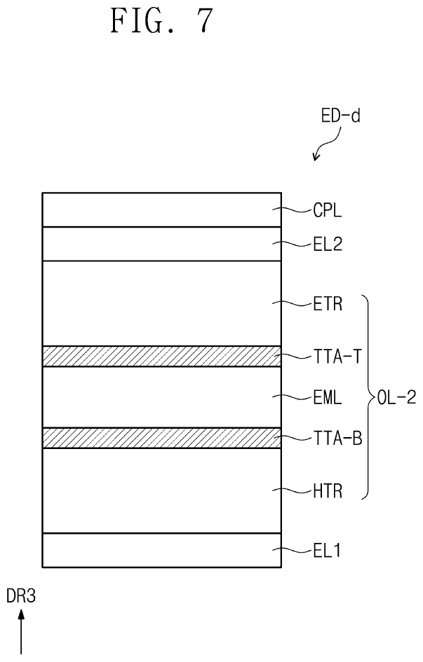

In comparison to the embodiments illustrated in FIGS. 3 to 6, the light emitting element ED-d illustrated in FIG. 7 is different at least in that two auxiliary layers TTA-T and TTA-B are included. The light emitting element ED-d according to an embodiment may include an upper auxiliary layer TTA-T disposed between a light emitting layer EML and an electron transport region ETR, and a lower auxiliary layer TTA-B disposed between a light emitting layer EML and a hole transport region HTR.

In the light emitting elements ED, ED-a, ED-b, ED-c, and ED-d, the first electrode EL1 may have conductivity. The first electrode EL1 may include a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a semi-transmissive electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide, for example, an indium tin oxide (ITO), an indium zinc oxide (IZO), a zinc oxide (ZnO), an indium tin zinc oxide (ITZO), or the like. If the first electrode EL1 is a semi-transmissive electrode or a reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, a compound thereof, or a mixture thereof (e.g., mixture of Ag and Mg). In another embodiment, the first electrode EL1 may have a multilayered structure including a reflective film or a semi-transmissive film, each of which is made of the aforementioned materials, and a transparent conductive film made of an indium tin oxide (ITO), an indium zinc oxide (IZO), a zinc oxide (ZnO), an indium tin zinc oxide (ITZO), or the like. For example, the first electrode EL1 may have a three-layered structure of ITO/Ag/ITO, but embodiments are not limited thereto. In an embodiment, the first electrode EL1 may include one of the aforementioned metal materials, a combination of two or more of the aforementioned metal materials, an oxide of the aforementioned metal materials, or the like. The first electrode EL1 may have a thickness in a range of about 700 Λ to about 10,000 Å. For example, the thickness of the first electrode EL1 may be in a range about 1,000 Å to about 3,000 Å.

The hole transport region HTR may be provided on the first electrode EL1. The hole transport region HTR may include at least one of the hole injection layer HIL, the hole transport layer HTL, a light emitting auxiliary layer (not illustrated), and the electron blocking layer EBL. The hole transport region HTR may have a thickness in a range of, for example, about 50 Å to about 15,000 Å. The light emitting auxiliary layer (not illustrated) may compensate a resonance distance according to wavelengths of light emitted from the light emitting layer EML, and may adjust the hole charge balance to increase light-emission efficacy. The light emitting auxiliary layer (not illustrated) may include a material that may be included in the hole transport region HTR. The electron blocking layer EBL is a layer that prevents electrons from being injected from the electron transport region ETR to the hole transport region HTR.

The hole transport region HTR may have a structure consisting of a layer consisting of a single material, a structure consisting of a layer including different materials, or a structure including multiple layers including different materials. For example, the hole transport region HTR may have a single-layered structure of a hole injection layer HIL or a hole transport layer HTL, or may have a single-layered structure made of a hole injection material or a hole transport material. In an embodiment, the hole transport region HTR may have a single-layered structure including different materials, or may have a structure in which a hole injection layer HIL/hole transport layer HTL, a hole transport layer HTL/electron blocking layer EBL, or a hole injection layer HIL/hole transport layer HTL/electron blocking layer EBL are stacked in sequence on the first electrode EL1. However, embodiments are not limited thereto. In an embodiment, the hole transport layer HTL may have a single-layered structure or a multilayered structure.

The hole transport layer HTL may be formed using various methods such as a vacuum deposition method, a spin coating method, a cast method, a Langmuir-Blodgett (LB) method, an inkjet printing method, a laser printing method, or a laser induced thermal imaging (LITI) method.

In the light emitting elements ED, ED-a, ED-b, ED-c, and ED-d according to embodiments, the hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), (4,4′4″-Tris(N,N-diphenylamino)triphenylamine (TDATA), 4,4′,4″-tris[N(2-naphthyl)-N-phenylamino]-triphenylamine (2-TNATA), Poly(3,4-ethylenedioxythiophene)/Poly(4-styrenesulfonate) (PEDOT/PSS), Polyaniline/Dodecylbenzenesulfonic acid (PANI/DBSA), Polyaniline/Camphor sulfonicacid (PANI/CSA), Polyaniline/Poly(4-styrenesulfonate) (PANI/PSS), N,N′-di(naphthalene-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], dipyrazino[2,3-f: 2′,3′-h]quinoxaline-2,3,6,7,10,11-hexacarbonitrile (HATCN), or the like.

In an embodiment, the hole transport region HTR may include a carbazole derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-Cyclohexylidene bis[N,N-bis(4-methylphenyl)benzenamine](TAPC), 4,4′-Bis[N,N′-(3-tolyl)amino]-3,3′-dimethylbiphenyl (HMTPD), 1,3-Bis(carbazol-9-yl)benzene (mCP), or the like.

In another embodiment, the hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

In the light emitting elements ED, ED-a, ED-b, ED-c and ED-d according to an embodiment, the light emitting layer EML may be provided on the hole transport region HTR. The light emitting layer EML may have a thickness t_{EM} in a range of, for example, about 50 Å to about 1,000 Å. For example, the light emitting layer EML may have a thickness t_{EM} in a range of about 50 Å to about 200 Å. For example, the light emitting layer EML may have the thickness t_{EM} in a range of about 100 Å to about 200 Å. The light emitting layer EML may have a structure consisting of a layer consisting of a single material, a structure consisting of a layer including different materials, or a structure including multiple layers including different materials.

In the light emitting elements ED, ED-a, ED-b, ED-c, and ED-d according to an embodiment, the light emitting layer EML may emit blue light. The light emitting layer EML may emit blue fluorescent light. However, embodiments are not limited thereto, and the light emitting layer EML may emit light in a wavelength region other than the blue light.

In an embodiment, the light emitting layer EML may include an anthracene derivative, a pyrene derivative, a fluoranthene derivative, a chrysene derivative, a dihydrobenzanthracene derivative, or a triphenylene derivative. For example, the light emitting layer EML may include an anthracene derivative or a pyrene derivative.

In an embodiment, the light emitting layer EML may include a host and a dopant, and the light emitting layer EML may include a compound represented by Formula E-1. The compound represented by Formula E-1 may be used as a fluorescence host material.

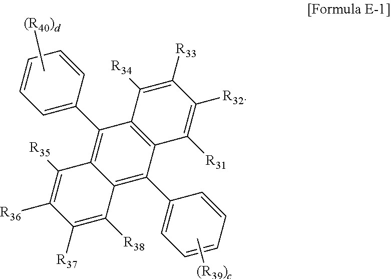

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compounds E1 to E20:

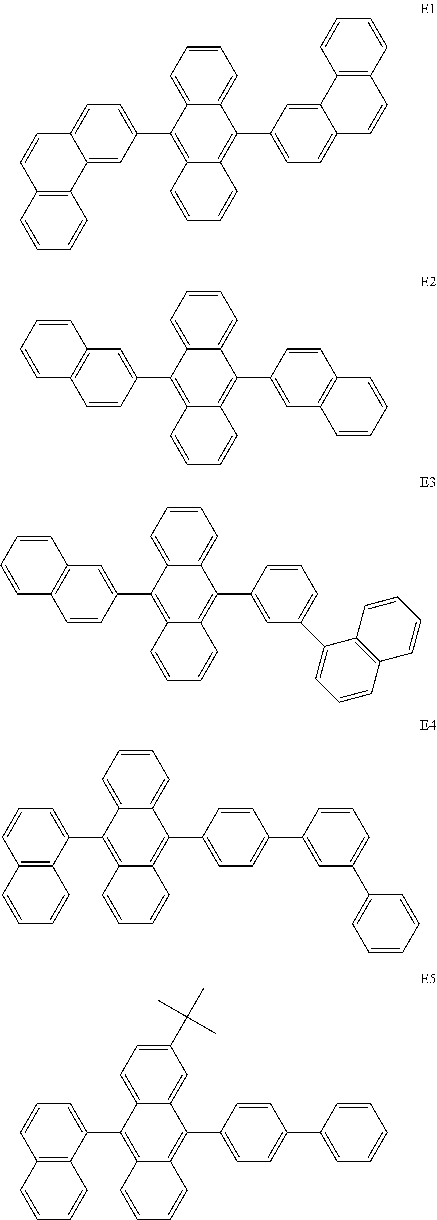

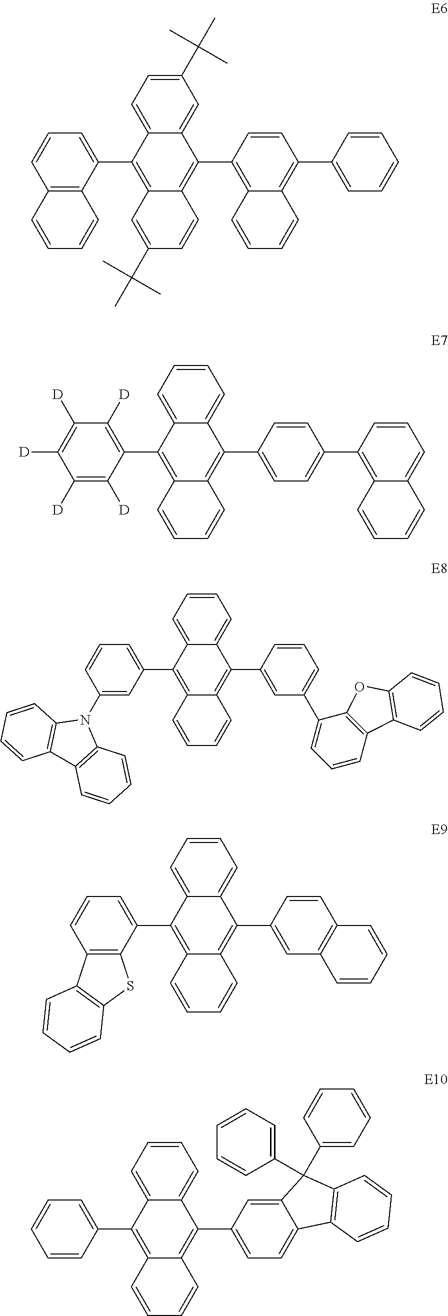

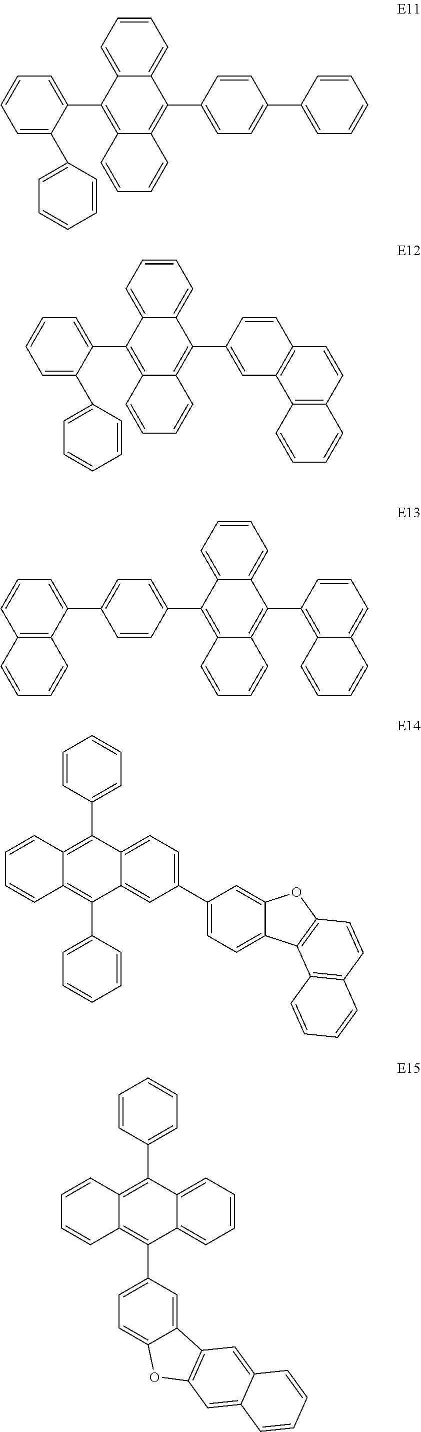

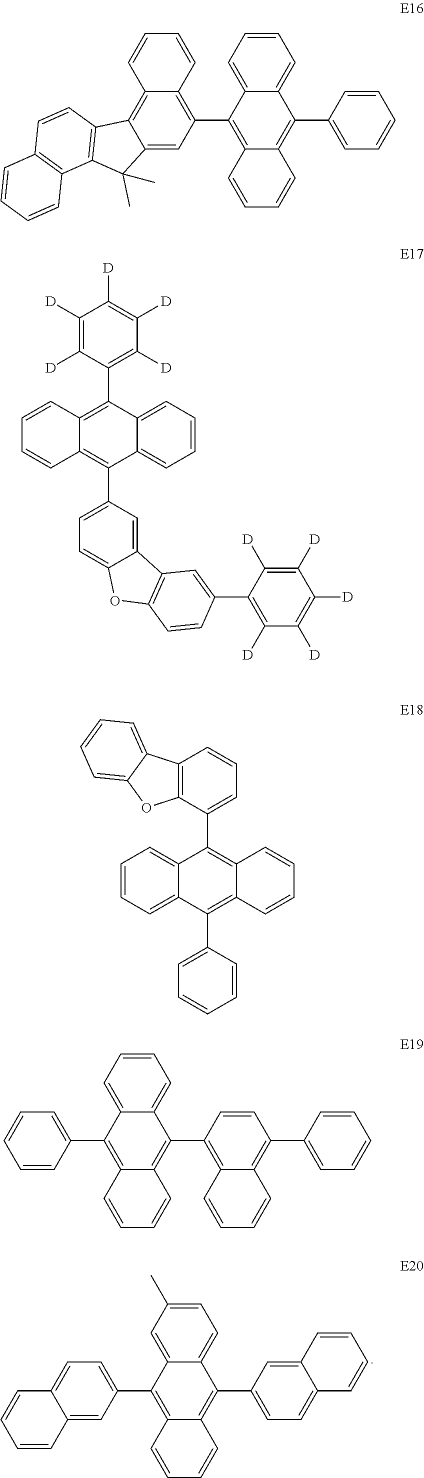

In an embodiment, the light emitting layer EML may further include, as the host material, a material of the related art. For example, the light emitting layer EML may include, as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), Bis[2-(diphenylphosphino)phenyl]ether oxide (DPEPO), 4,4′-bis(N-carbazolyl)-1,1′-biphenyl (CBP), (1,3-Bis(carbazol-9-yl)benzene (mCP), 2,8-Bis(diphenylphosphoryl)dibenzo[b,d]furan (PPF), 4,4′,4″-Tris(carbazol-9-yl)-triphenylamine (TCTA), and 1,3,5-tris(1-phenyl-1H-benzo[d]imidazole-2-yl)benzene (TPBi). However, embodiments are not limited thereto, and, for example, tris(8-hydroxyquinolino)aluminum (Alq₃), 9,10-di(naphthalene-2-yl)anthracene (ADN), (2-tert-butyl-9,10-di(naphth-2-yl)anthracene (TBADN), distyrylarylene (DSA), 4,4′-bis(9-carbazolyl)-2,2′-dimethyl-biphenyl (CDBP), (2-Methyl-9,10-bis(naphthalen-2-yl)anthracene (MADN), Hexaphenyl cyclotriphosphazene (CP1), 1,4-Bis(triphenylsilyl)benzene (UGH2), Hexaphenylcyclotrisiloxane (DPSiO₃), Octaphenylcyclotetra siloxane (DPSiO₄), or the like, may be used as the host material.

In an embodiment, the light emitting layer EML may include a compound represented by Formula F-a. The compound represented by Formula F-a may be used as a fluorescence dopant material.

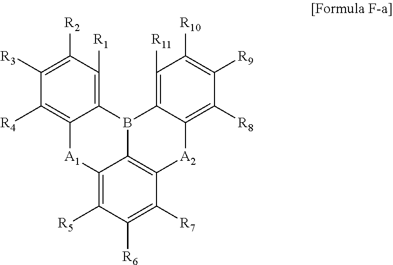

In Formula F-a, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-a, R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-a, A₁ and A₂ may each independently be bonded to a substituent of an adjacent ring to form a condensed ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the light emitting layer EML may include, a material of the related art as a dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and a derivative thereof (e.g., 2,5,8,11-Tetra-t-butylperylene (TBP)), pyrene and a derivative thereof (e.g., 1,1-dipyrene, 1,4-dipyrenylbenzene, 1,4-Bis(N, N-Diphenylamino)pyrene), or the like.

In an embodiment, the light emitting layer EML may include a host and a dopant, and the dopant may be a blue dopant having a maximum emission peak in a range of about 400 nm to about 450 nm. For example, in an embodiment, the light emitting layer EML may include a blue host material represented by Formula E-1 described above, and a blue fluorescent dopant which is excited by the blue host material to emit the light having the maximum emission peak in a range of about 400 nm to about 450 nm.

In the light emitting elements ED, ED-a, ED-b, ED-c, and ED-d according to an embodiment, the electron transport region ETR may be provided on the light emitting layer EML. The electron transport region ETR may have a structure consisting of a layer consisting of a single material, a structure consisting of a layer including different materials, or a structure including multiple layers including different materials.

For example, the electron transport region ETR may have a single-layered structure of an electron injection layer EIL or an electron transport layer ETL, or may have a single-layered structure that includes an electron injection material or an electron transport material. The electron transport region ETR may have a single-layered structure including different materials. In embodiments, the electron transport region ETR may have a structure in which the electron transport layer ETL/electron injection layer EIL or the hole blocking layer HBL/electron transport layer ETL/electron injection layer EIL may be stacked in order on the light emitting layer EML, but embodiments are not limited thereto. The electron transport region ETR may have a thickness of, for example, in a range of about 1,000 Å to about 1,500 Å.

The electron transport region ETR may be provided using various methods such as a vacuum deposition method, a spin coating method, a cast method, a Langmuir-Blodgett (LB) method, an inkjet printing method, a laser printing method, or a laser induced thermal imaging (LITI) method.

In an embodiment, the electron transport region ETR may include an anthracene-based compound. However, embodiments are not limited thereto, and the electron transport region ETR may include, for example, Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), beryllium bis(benzoquinolin-10-olate) (Bebg₂), 9,10-di(naphthalene-2-yl)anthracene (ADN), 1,3-Bis[3,5-di(pyridin-3-yl)phenyl]benzene (BmPyPhB), and any compound thereof.

In an embodiment, the electron transport region ETR may include a halogenated metal such as LiF, NaCl, CsF, RbCl, RbI, CuI, or KI, a lanthanum group metal such as Yb, or a co-deposition material of the halogenated metal and the lanthanum group metal. For example, the electron transport region ETR may include KI:Yb, RbI:Yb, LiF:Yb, or the like, as a co-deposition material. A metal oxide such as Li₂O or BaO, 8-hydroxyl-Lithium quinolate (Liq), or the like may be used for the electron transport region ETR, but embodiments are not limited thereto. The electron transport region ETR may also include a material in which an electron transport material and an insulating organometallic salt are mixed. The organometallic salt may be a material having an energy band gap greater than or equal to about 4 eV. For example, the organometallic salt may include metal acetate, metal benzoate, metal acetoacetate, metal acetylacetonate, or metal stearate.

The electron transport region ETR may further include, in addition to the aforementioned materials, at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen), but embodiments are not limited thereto.

In an embodiment, the second electrode EL2 may be provided on the electron transport region ETR. The second electrode EL2 may be a common electrode. The second electrode EL2 may be a cathode or an anode, but embodiments are not limited thereto. For example, if the first electrode EL1 is an anode, the second electrode EL2 may be a cathode, and if the first electrode EL1 is a cathode, the second electrode EL2 may be an anode.

In an embodiment, the second electrode EL2 may be a transmissive electrode, a semi-transmissive electrode, or a reflective electrode. If the second electrode EL2 is a transmissive electrode, the second electrode EL2 may include a transparent metal oxide, for example, an indium tin oxide (ITO), an indium zinc oxide (IZO), a zinc oxide (ZnO), an indium tin zinc oxide (ITZO), or the like.

If the second electrode EL2 is a semi-transmissive electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or compound thereof, or a mixture thereof (e.g., AgMg, AgYb, or MgYb). In an embodiment, the second electrode EL2 may have a multilayered structure that includes a reflective film or a semi-transmissive film made of the aforementioned metal materials, and a transparent conductive film made of an indium tin oxide (ITO), an indium zinc oxide (IZO), a zinc oxide (ZnO), an indium tin zinc oxide (ITZO), or the like. For example, the second electrode EL2 may include the aforementioned metal material, a combination of two or more of the aforementioned metal materials, an oxide of the aforementioned metal materials, or the like.

Although not illustrated in the drawings, the second electrode EL2 may be electrically connected to an auxiliary electrode. When the second electrode EL2 is electrically connected to an auxiliary electrode, resistance of the second electrode EL2 may be reduced.

In an embodiment, the capping layer CPL may be further disposed on the second electrode EL2. The capping layer CPL may have a multilayered structure or a single-layered structure.

In an embodiment, the capping layer CPL may include an organic layer or an inorganic layer. For example, if the capping layer CPL includes an inorganic substance, the inorganic substance may include an alkaline metal compound such as LiF, an alkaline earth metal compound such as MgF₂, SiON, SiNₓ, SiO_{y}, or the like.

For example, if the capping layer CPL includes an organic substance, the organic substance may include a-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-Tris (carbazol-9-yl) triphenylamine (TCTA), or the like, or may include an epoxy resin, or an acrylate such as a methacrylate. However, embodiments are not limited thereto, and the capping layer CPL may include at least one of Compounds P1 to P5.

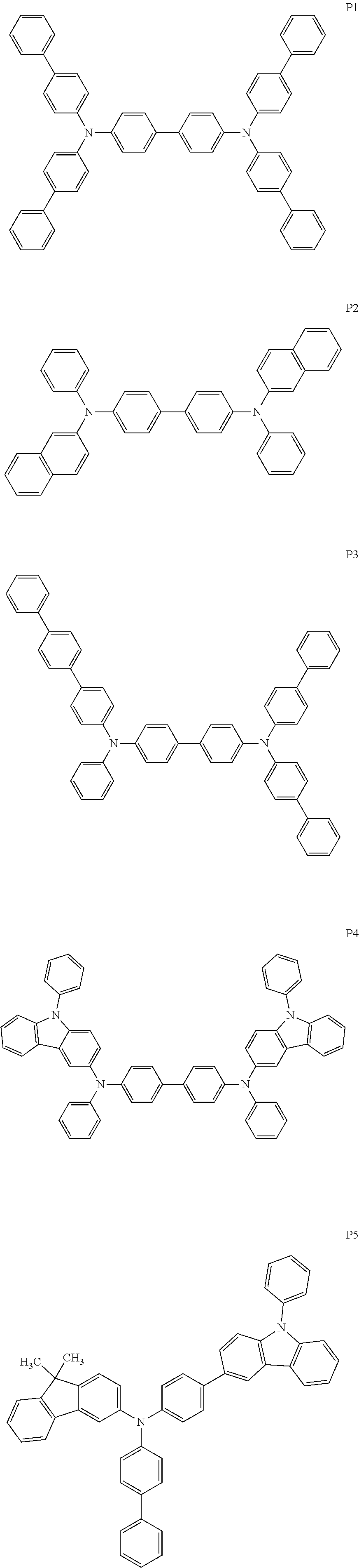 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index greater than or equal to about 1.6 or more. In an embodiment, the refractive index of the capping layer CPL with respect to light in a wavelength region in a range of about 550 nm to about 660 nm may be greater than or equal to about 1.6.

Referring to FIG. 3, the auxiliary layer TTA may be directly disposed between the light emitting layer EML and the electron transport region ETR. The auxiliary layer TTA may include an anthracene compound represented by Formula 1:

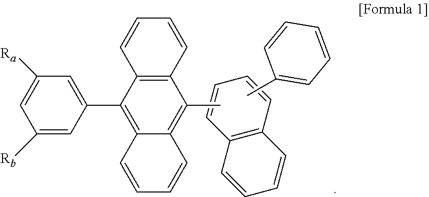

In Formula 1, Rₐ and R_{b} may be each independently be a group represented by Formula 2.

In an embodiment, the anthracene compound represented by Formula 1 may be represented by one of Formulae 1-1 to 1-6:

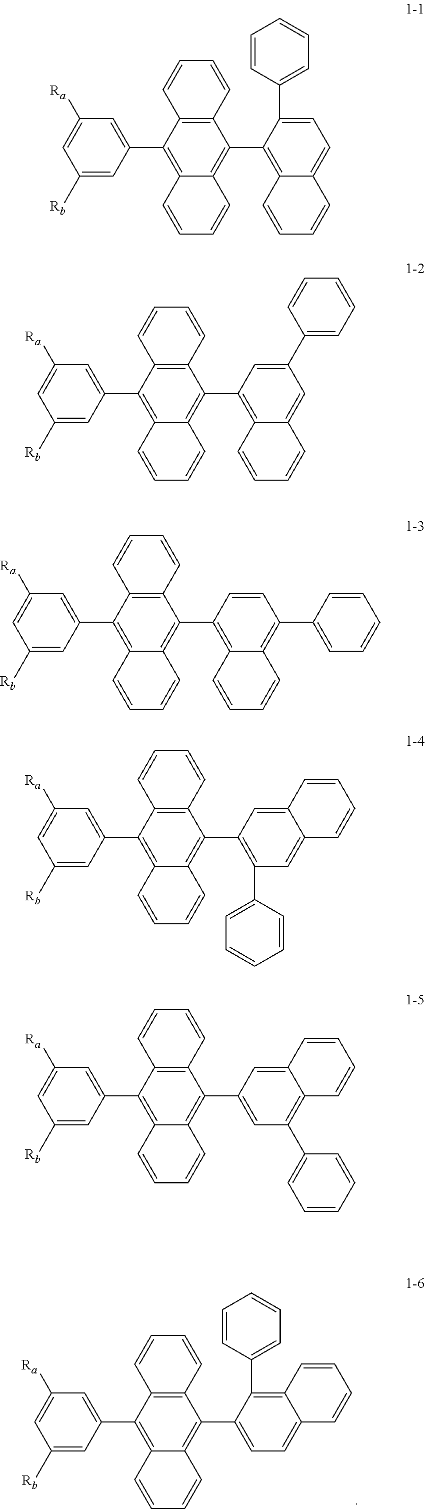

In Formulae 1-1 to 1-6, Rₐ and R_{b} may each independently be a group represented by Formula 2. In Formulae 1-1 to 1-6, Rₐ and R_{b} may be the same as or different from each other.

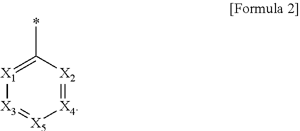

In Formula 2, X₁ to X₅ may each independently be N or CH.

In an embodiment, the group represented by Formula 2 may be a group represented by one of Formulae 2a to 2h.

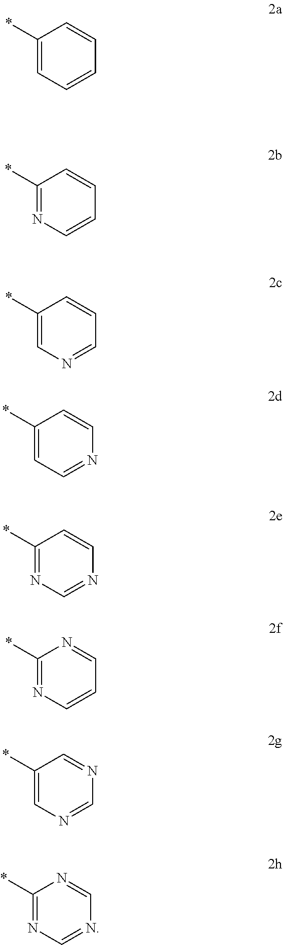

In an embodiment, the anthracene compound represented by Formula 1 may be selected from Compound Group 1. In an embodiment, the auxiliary layer TTA may include at least one compound selected from Compound Group 1:

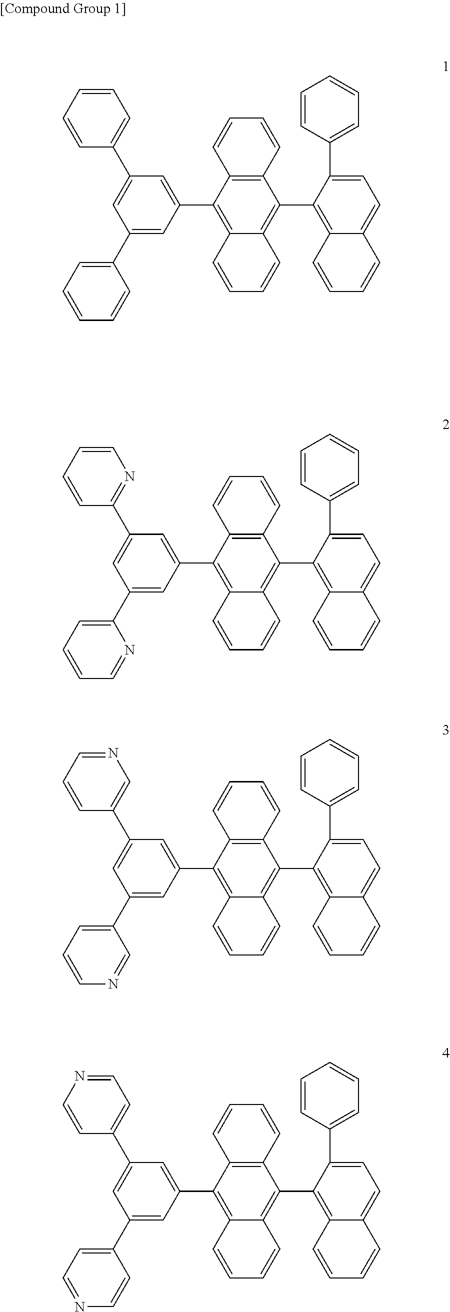

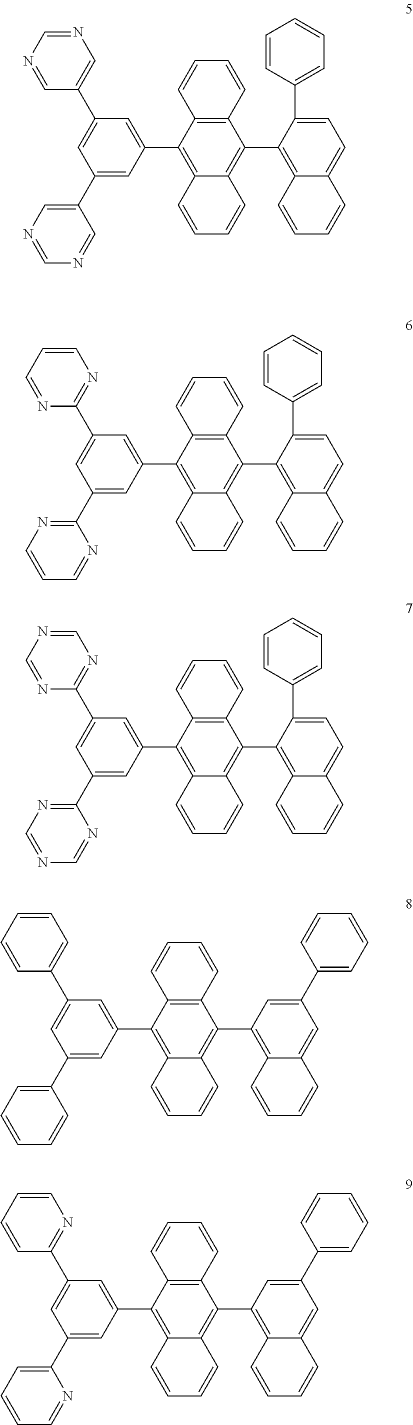

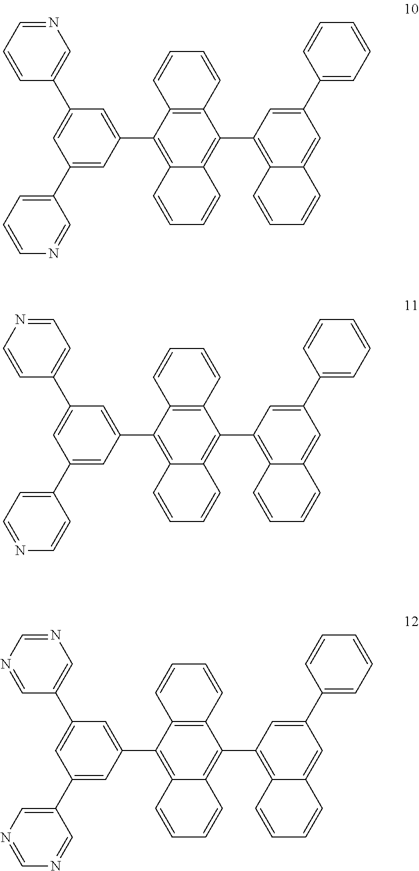 [SMILES: c1ccc(-c2cc(-c3c4ccccc4c(-c4cc(-c5cccnc5)cc(-c5cccnc5)c4)c4ccccc34)c3ccccc3c2)cc1 ; c1ccc(-c2cc(-c3c4ccccc4c(-c4cc(-c5ccncc5)cc(-c5ccncc5)c4)c4ccccc34)c3ccccc3c2)cc1 ; c1ccc(-c2cc(-c3c4ccccc4c(-c4cc(-c5cncnc5)cc(-c5cncnc5)c4)c4ccccc34)c3ccccc3c2)cc1]

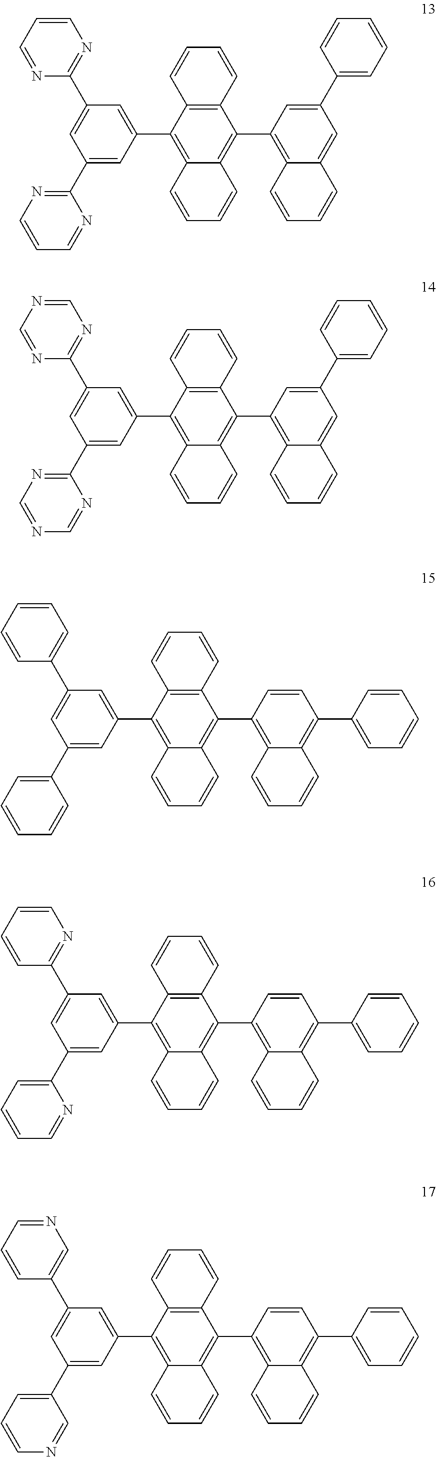

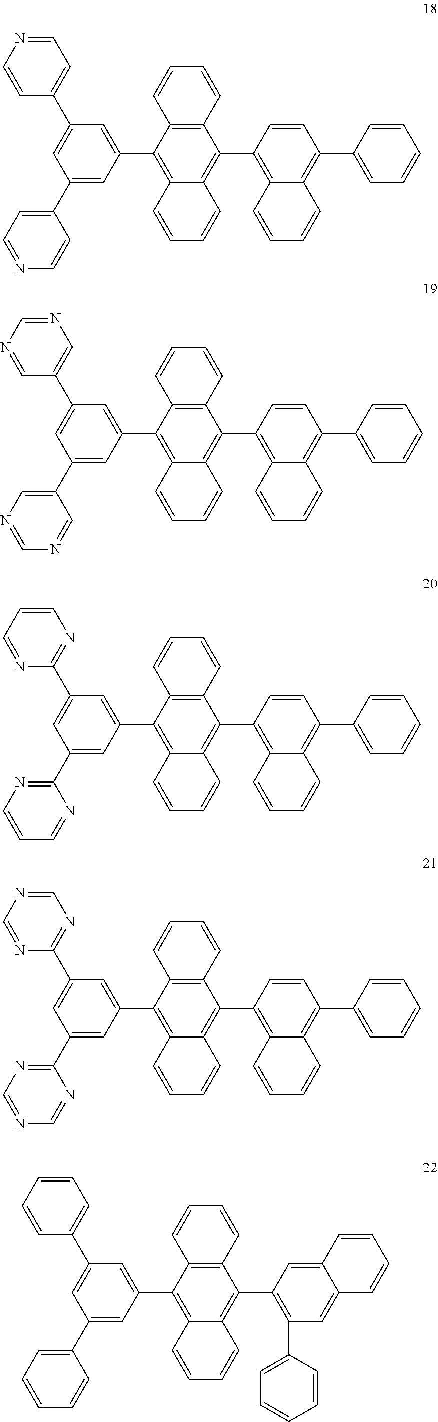

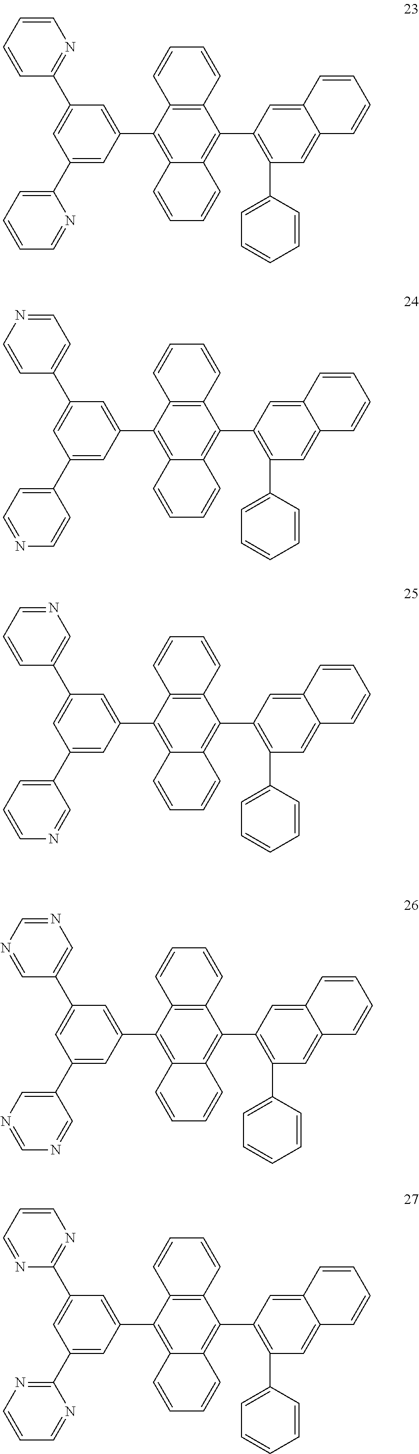 [SMILES: c1ccc(-c2cc3ccccc3cc2-c2c3ccccc3c(-c3cc(-c4ccccn4)cc(-c4ccccn4)c3)c3ccccc23)cc1 ; c1ccc(-c2cc3ccccc3cc2-c2c3ccccc3c(-c3cc(-c4ccncc4)cc(-c4ccncc4)c3)c3ccccc23)cc1 ; c1ccc(-c2cc3ccccc3cc2-c2c3ccccc3c(-c3cc(-c4cccnc4)cc(-c4cccnc4)c3)c3ccccc23)cc1 ; c1ccc(-c2cc3ccccc3cc2-c2c3ccccc3c(-c3cc(-c4cncnc4)cc(-c4cncnc4)c3)c3ccccc23)cc1 ; c1ccc(-c2cc3ccccc3cc2-c2c3ccccc3c(-c3cc(-c4ncccn4)cc(-c4ncccn4)c3)c3ccccc23)cc1]

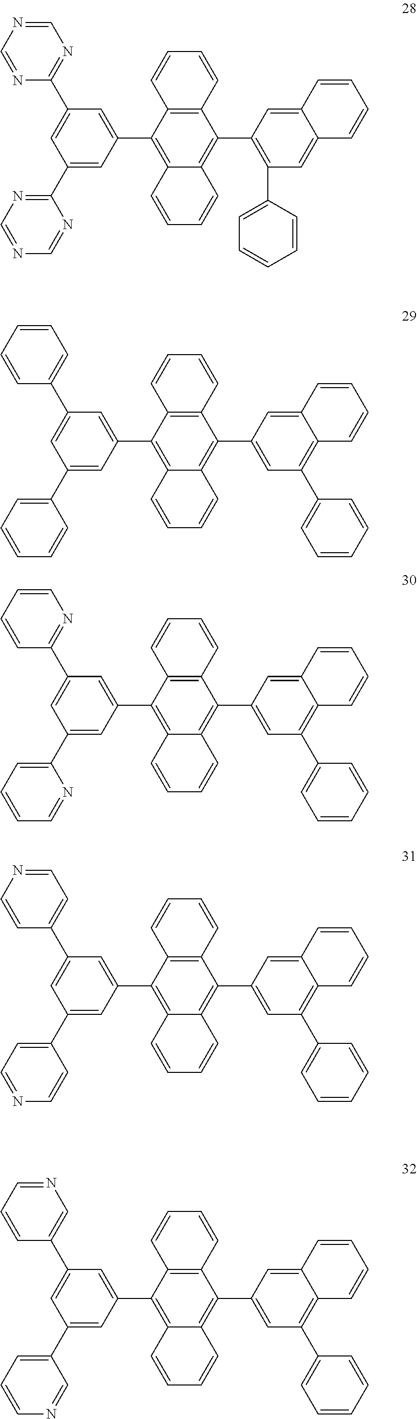

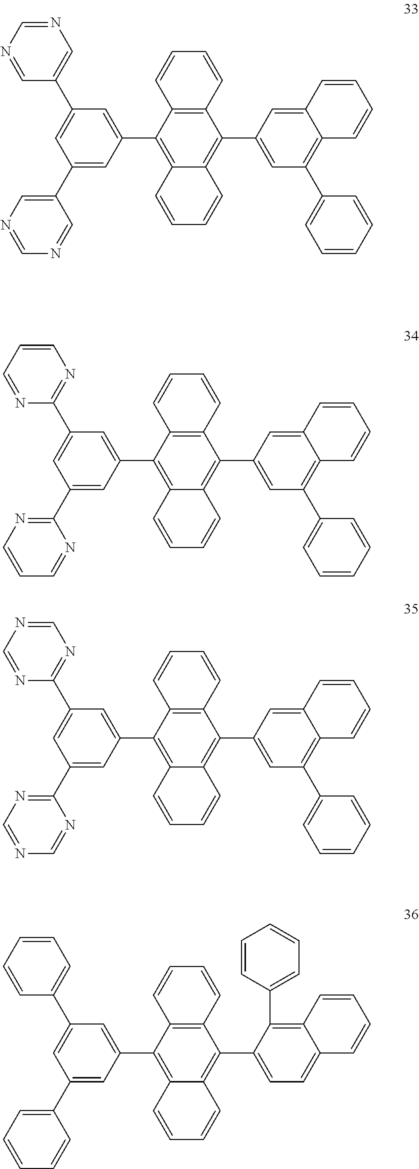

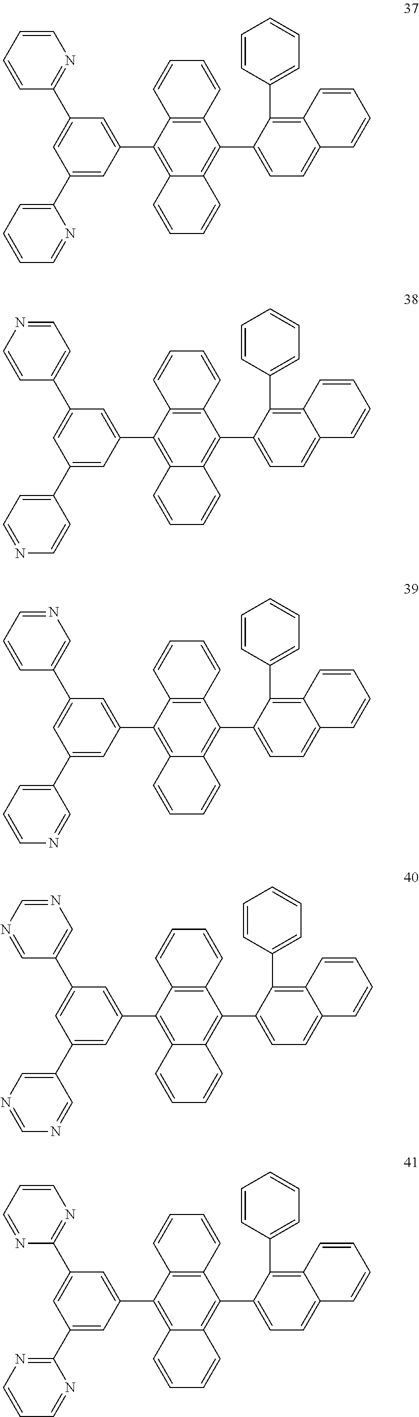 [SMILES: c1ccc(-c2c(-c3c4ccccc4c(-c4cc(-c5ccccn5)cc(-c5ccccn5)c4)c4ccccc34)ccc3ccccc23)cc1 ; c1ccc(-c2c(-c3c4ccccc4c(-c4cc(-c5ccncc5)cc(-c5ccncc5)c4)c4ccccc34)ccc3ccccc23)cc1 ; c1ccc(-c2c(-c3c4ccccc4c(-c4cc(-c5cccnc5)cc(-c5cccnc5)c4)c4ccccc34)ccc3ccccc23)cc1 ; c1ccc(-c2c(-c3c4ccccc4c(-c4cc(-c5cncnc5)cc(-c5cncnc5)c4)c4ccccc34)ccc3ccccc23)cc1 ; c1ccc(-c2c(-c3c4ccccc4c(-c4cc(-c5ncccn5)cc(-c5ncccn5)c4)c4ccccc34)ccc3ccccc23)cc1]

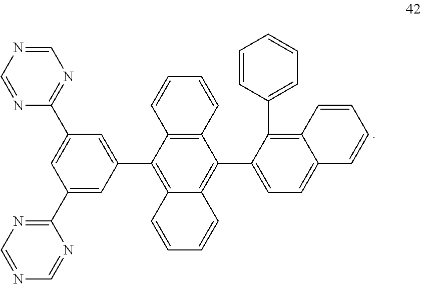 [SMILES: c1ccc(-c2c(-c3c4ccccc4c(-c4cc(-c5ncncn5)cc(-c5ncncn5)c4)c4ccccc34)ccc3ccccc23)cc1]

In embodiments, the auxiliary layer TTA may not include a dopant. In embodiments, the auxiliary layer TTA may include only the anthracene compound represented by Formula 1. For example, auxiliary layer TTA may consist of the anthracene compound represented by Formula 1.

The auxiliary layer TTA may have a thickness t_{TA} in a range of about 10 Å to about 50 Å. As the auxiliary layer TTA has a small thickness in a range of about 10 Å to about 50 Å in a single film form, a distance between anthracene compound molecules in the auxiliary layer TTA may be decreased. Accordingly, upon excitation of the anthracene compound, a triplet density in the auxiliary layer TTA may be increased. If the thickness t_{TA} of the auxiliary layer TTA is less than about 10 Å, film formation characteristics of the auxiliary layer TTA may be insufficient for triplet-triplet annihilation, and if the thickness t_{TA} of the auxiliary layer TTA is greater than about 50 Å, a density of the anthracene compounds included in the auxiliary layer TTA may not be sufficient to promote molecular collisions.

In an embodiment, as the undoped auxiliary layer TTA includes the anthracene compound at a high density within a relatively small thickness range of about 10 Å to about 50 Å, triplet excitons of the anthracene compounds may collide with each other to transition into a singlet state. The excitons in a singlet state may be transferred to a neighboring light emitting layer EML to induce light emission of the dopant in the light emitting layer. For example, as the auxiliary layer TTA disposed adjacent to the light emitting layer EML includes the above-described anthracene compound, the light emitting element ED according to an embodiment may induce additional fluorescence emission of the light emitting layer EML by using triplet-triplet annihilation between the anthracene compound molecules. Accordingly, the light emitting element ED according to an embodiment, in which the auxiliary layer TTA including the above-described anthracene compound and does not include a dopant, may exhibit improved luminous efficacy as compared to a light emitting element of the related art that includes a light emitting layer using only a singlet state.

In an embodiment, a thickness t_{TA} of the auxiliary layer TTA may be less than a thickness t_{EM} of the light emitting layer EML. As the auxiliary layer TTA has a smaller thickness than the light emitting layer EML, the anthracene compounds according to embodiments may be included at high densities in the auxiliary layer TTA, and accordingly, triplet-triplet annihilation in the auxiliary layer TTA may more readily occur.

In the light emitting elements ED-a, ED-b, ED-c, and ED-d according to an embodiment illustrated in FIGS. 4 to 7 in addition to FIG. 3, the auxiliary layers TTA, TTA-T and TTA-B directly disposed either or both of above and below the light emitting layers EML may be included to induce triplet-triplet annihilation between the anthracene compound molecules, thereby increasing the fluorescence emission in the light emitting layers EML. For example, the light emitting elements according to an embodiment including the auxiliary layers TTA, TTA-T, and TTA-B disposed adjacent to the light emitting layers EML and including the above-described anthracene compounds may exhibit improved luminous efficacy characteristics.

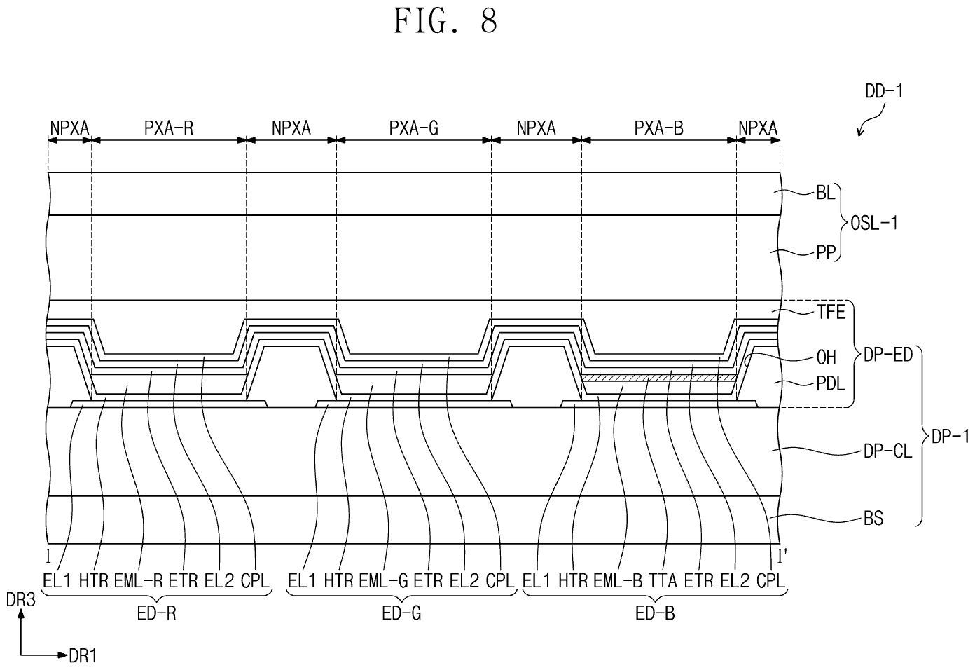

FIG. 8 is a schematic cross-sectional view of a display device according to an embodiment. FIG. 8 may be a schematic cross-sectional view of a portion corresponding to line I-I′ in FIG. 1. Referring to FIG. 8, a display device DD-1 according to an embodiment may include a display panel DP-1 including a display element layer DP-ED, and a light control panel OSL-1 disposed on the display panel DP-1. Hereinafter, the display device DD-1 according to an embodiment will be described with reference to FIG. 8, the features that have been described above with reference to FIGS. 1 to 7 will not be explained again, and the differing features will be described.

The display device DD-1 according to an embodiment illustrated in FIG. 8 may include a base layer BS, a circuit layer DP-CL provided on the base layer BS, and a display element layer DP-ED. The display element layer DP-ED may include light emitting elements ED-R, ED-G, and ED-B.

The display panel DP-1 may include non-emission areas NPXA and pixel areas PXA-R, PXA-G, and PXA-B. The pixel areas PXA-R, PXA-G, and PXA-B may each be an area through which light generated from each of the light emitting elements ED-R, ED-G, and ED-B is emitted.

The pixel areas PXA-R, PXA-G, and PXA-B may be areas separated by a pixel defining film PDL. The non-emission areas NPXA may be areas between neighboring pixel areas PXA-R, PXA-G, and PXA-B, and may be an area that corresponds to the pixel defining film PDL. Light emitting layers EML-R, EML-G, and EML-B of the light emitting elements ED-R, ED-G, and ED-B may be respectively separated by being disposed in openings OH defined in the pixel defining film PDL.

In the display device DD-1 according to an embodiment, the light emitting elements ED-R, ED-G, and ED-B may emit light in different wavelength regions from each other. For example, the display device DD-1 according to an embodiment may include a first light emitting element ED-R that emits red light, a second light emitting element ED-G that emits green light, and a third light emitting element ED-B that emits blue light. For example, a red light emitting area PXA-R, a green light emitting area PXA-G, and a blue light emitting area PXA-B of the display device DD-1 may respectively correspond to the first light emitting element ED-R, the second light emitting element ED-G, and the third light emitting element ED-B.

The light emitting elements ED-R, ED-G, and ED-B may include first electrodes EL1, hole transport regions HTR, light emitting layers EML-R, EML-G, and EML-B, electron transport regions ETR, second electrodes E12, and capping layers CPL. In an embodiment, the third light emitting element ED-B that emits the blue light may include an auxiliary layer TTA disposed between the light emitting layer EML-B and the electron transport region ETR. In an embodiment, the auxiliary layer TTA may be directly disposed between the light emitting layer EML-B and the electron transport region ETR. The auxiliary layer TTA may be the same auxiliary layer TTA as described with reference to FIGS. 3 to 7. In an embodiment as illustrated in FIG. 8, the third light emitting element ED-B may include the structure of the light emitting element described with reference to FIGS. 3 to 7. Accordingly, in an embodiment, the third light emitting element ED-B may exhibit an effect that luminous efficacy of the light emitting layer EML-B is improved due to singlet excitons transferred from the auxiliary layer TTA.

In FIG. 8, the first light emitting element ED-R, the second light emitting element ED-G, and the third light emitting element ED-B may each include a first electrode EL1, a second electrode EL2, a hole transport region HTR, an electron transport region ETR, and a capping layer CPL, which may each be the same as what has been described above with reference to FIGS. 3 to 7. Components of the light emitting layer EML-B of the third light emitting element ED-B may be different at least in that the light emitting layer EML-R of the first light emitting element ED-R may include host and dopant materials that emit red light, and the light emitting layer EML-G of the second light emitting element ED-G may include host and dopant materials that emit green light.

Although not shown in the drawings, in the display device DD-1, the first light emitting element ED-R and the second light emitting element ED-G may also each include the auxiliary layer TTA. The auxiliary layer TTA may be directly disposed on at least one of a top surface and a bottom surface of each of the light emitting layers EML-R and EML-G.

In the display device DD-1 according to an embodiment, the light control panel OSL-1 may include an optical layer PP. The optical layer PP may be disposed on the display panel DP-1 and control light that is reflected from the display panel DP-1 from an external light. The optical layer PP may include, for example, a polarizing layer or a color filter layer. Although not shown in the drawings, the optical layer PP may be omitted in the display device DD-1.

A base substrate BL may be disposed on the optical layer PP. The base substrate BL may provide a base surface on which the optical layer PP is disposed. The base substrate BL may be a glass substrate, a metal substrate, a plastic substrate, or the like. However, embodiments are not limited thereto, and the base substrate BL may include an inorganic layer, an organic layer, or a composite material layer. Although not in the drawings, the base substrate BL may be omitted.

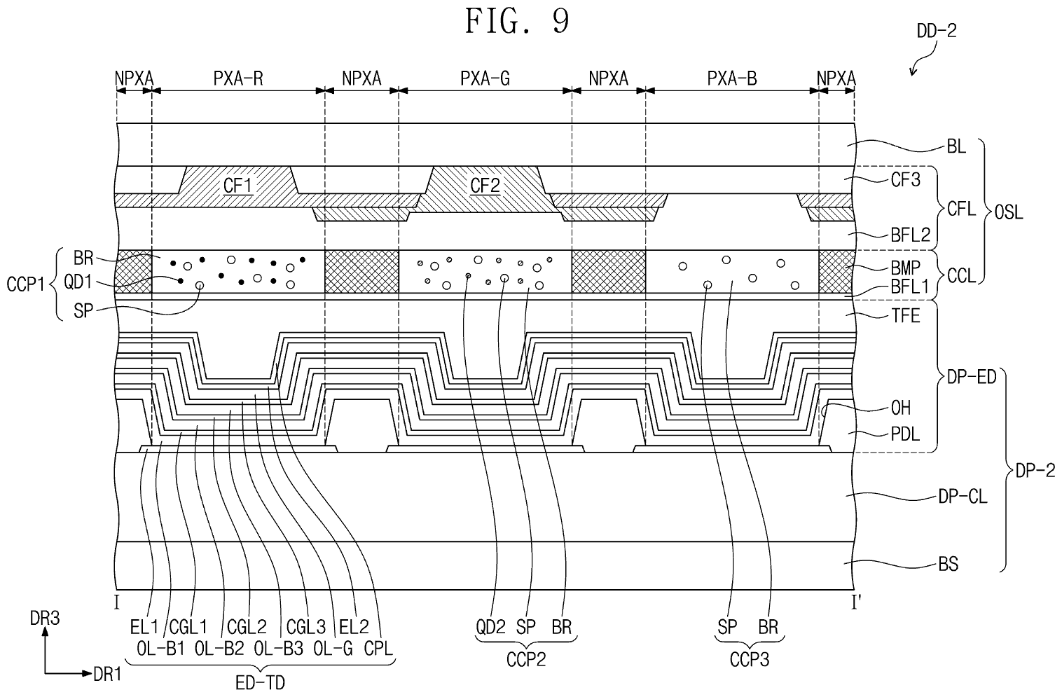

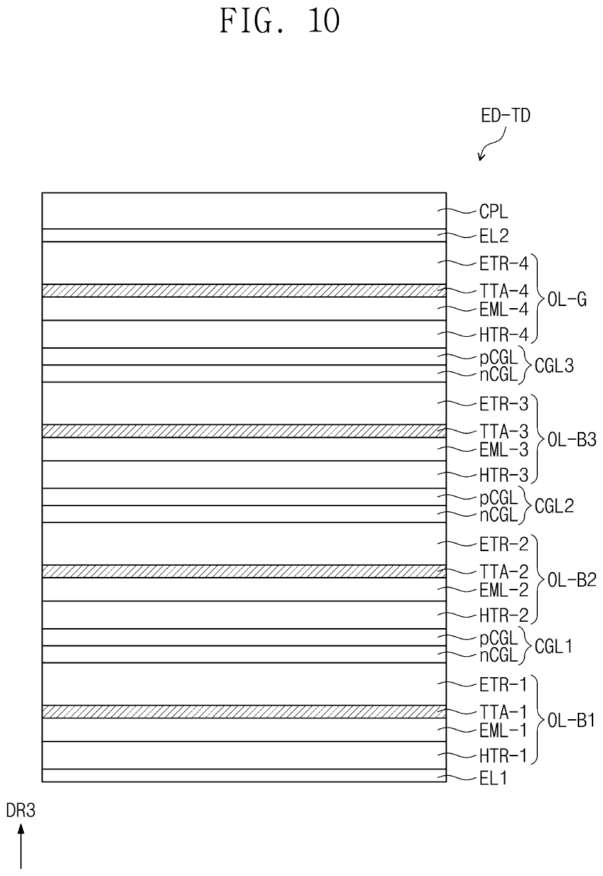

FIG. 9 is a schematic cross-sectional view of a display device according to an embodiment. FIG. 9 is a schematic cross-sectional view of a portion corresponding to line I-I′ in FIG. 1. FIG. 10 is a schematic cross-sectional view of a light emitting element according to an embodiment. FIG. 10 illustrates, in more detail, a light emitting element ED-TD included in a display device DD-2 in FIG. 9.

Referring to FIG. 9, the display device DD-2 according to an embodiment may include a display panel DP-2 including a display element layer DP-ED, and a light control panel OSL disposed on the display panel DP-2. In the explanation of the display device DD-2 and the light emitting element ED-TD according to an embodiment with reference to FIGS. 9 and 10, the features that have been described above with reference to FIGS. 1 to 7 will not be explained again, and the differing features will be described.

In the display device DD-2 according to an embodiment, the display panel DP-2 may include a base layer BS, a circuit layer DP-CL, and the display element layer DP-ED. In the display device DD-2 according to an embodiment, the light control panel OSL may be disposed on the display panel DP-2. The light control panel OSL may include a light control layer CCL, and may further include a color filter layer CFL, a barrier layer BFL2, a base substrate BL, and the like.

In the display device DD-2 according to an embodiment, the light emitting element ED-TD may include light emitting structures OL-B1, OL-B2, and OL-B3. At least one of the light emitting structures OL-B1, OL-B2, and OL-B3 may include the auxiliary layer including the anthracene compound described above. Accordingly, the light emitting element ED-TD may exhibit improved luminous efficacy characteristics by using triplet-triplet annihilation in the auxiliary layer.

In an embodiment, the light emitting element ED-TD may include a first electrode EL1 and a second electrode EL2 facing each other, and the light emitting structures OL-B1, OL-B2, OL-B3, and OL-G provided to be stacked in that order between the first electrode EL1 and the second electrode EL2 and in the thickness direction, but embodiments are not limited thereto. For example, the light emitting element ED-TD according to an embodiment may include three or more light emitting structures disposed between the first electrode EL1 and the second electrode EL2. The light emitting element ED-TD may include charge generation layers CGL1, CGL2, and CGL3, each of which is disposed between the light emitting structures OL-B1, OL-B2, OL-B3, and OL-G.

The light emitting structures OL-B1, OL-B2, OL-B3, and OL-G may each be disposed, in common, on the entirety of pixel areas PXA-R, PXA-G, and PXA-B. However, embodiments are not limited thereto. At least one of the light emitting structures OL-B1, OL-B2, OL-B3, and OL-G may be separately provided for each of first to third pixel areas PXA-R, PXA-G, and PXA-B. In an embodiment, the at least one light emitting structures OL-B1, OL-B2, OL-B3, and OL-G may be patterned in the openings OH and may be separately provided for each of first to third pixel areas PXA-R, PXA-G, and PXA-B.

The charge generation layers CGL1, CGL2, and CGL3 may each be disposed, in common, on the entirety of the pixel areas PXA-R, PXA-G, and PXA-B. However, embodiments are not limited thereto.

Referring to FIGS. 9 and 10, the light emitting element ED-TD according to an embodiment may include a first light emitting structure OL-B1, a second light emitting structure OL-B2, a third light emitting structure OL-B3, and a fourth light emitting structure OL-G which may be stacked in that order, but embodiments are not limited thereto. For example, in an embodiment, the first light emitting structure OL-B1, the second light emitting structure OL-B2, and the third light emitting structure OL-B3 may each be a blue light emitting structure that emits blue light, and the fourth light emitting structure OL-G may be a green light emitting structure. However, embodiments are not limited thereto, and a position of the green light emitting structure and the number of the green light emitting structure included in the light emitting element ED-TD may be changed.

The light emitting element ED-TD according to an embodiment may include a first charge generation layer CGL1 disposed between the first light emitting structure OL-B1 and the second light emitting structure OL-B2, a second charge generation layer CGL2 disposed between the second light emitting structure OL-B2 and the third light emitting structure OL-B3, and a third charge generation layer CGL3 disposed between the third light emitting structure OL-B3 and the fourth light emitting structure OL-G.

When a voltage is applied to the light emitting element ED-TD, the charge generation layers CGL1, CGL2, and CGL3 may generate charges (for example, electrons and holes) by forming a complex through an oxidation-reduction reaction. The charge generation layers CGL1, CGL2, and CGL3 may each provide the generated charges to adjacent light emitting structures OL-B1, OL-B2, OL-B3, and OL-G. The charge generation layers CGL1, CGL2, and CGL3 may increase efficacy of current generated from the adjacent light emitting structures OL-B1, OL-B2, OL-B3, and OL-G, and may serve to adjust the balance of the charges between the adjacent light emitting structures OL-B1, OL-B2, OL-B3, and OL-G.

The charge generation layers CGL1, CGL2, and CGL3 may each have a layer structure in which an n-type charge generation layer nCGL and a p-type charge generation layer pCGL are bonded to each other.

The n-type charge generation layer nCGL may be a charge generation layer that provides electrons to the adjacent light emitting structures OL-B1, OL-B2, OL-B3, and OL-G. The n-type charge generation layer nCGL may be a layer in which a base material is doped with an n-dopant. The p-type charge generation layer pCGL may be a charge generation layer that provides holes to the adjacent light emitting structures OL-B1, OL-B2, OL-B3, and OL-G. The p-type charge generation layer pCGL may be a layer in which a base material is doped with a p-dopant.

Although not illustrated in the drawings, a buffer layer may be further disposed between the n-type charge generation layer nCGL and the p-type charge generation layer pCGL.

The charge generation layers CGL1, CGL2, and CGL3 may each include an n-type aryl amine-based material or a p-type metal oxide. For example, the charge generation layers CGL1, CGL2, and CGL3 may each include a charge generation compound such as an aryl amine-based organic compound, a metal, a metal oxide, a metal carbide, a metal fluoride, or a mixture thereof.

Examples of an aryl amine-based organic compound may include α-NPD, 2-TNATA, TDATA, MTDATA, spiro-TAD, or spiro-NPB. Examples of a metal may include cesium (Cs), molybdenum (Mo), vanadium (V), titanium (Ti), tungsten (W), barium (Ba), or lithium (Li). Examples of a metal oxide, a metal carbide, or a metal fluoride may include Re₂O₇, MoO₃, V₂O₅, WO₃, TiO₂, Cs₂CO₃, BaF, LiF, and CsF.

The light emitting structures OL-B1, OL-B2, OL-B3, and OL-G may respectively include light emitting layers EML-1, EML-2, EML-3, and EML-4. The light emitting structures OL-B1, OL-B2, OL-B3, and OL-G may respectively include stacked hole transport region HTR-1, HTR-2, HTR-3, and HTR-4, the light emitting layers EML-1, EML-2, EML-3, and EML-4, and electron transport region ETR-1, ETR-2, ETR-3, and ETR-4. For example, the light emitting element ED-TD according to an embodiment may be a light emitting element having a Tandem structure including light emitting layers stacked in the thickness direction.

In an embodiment, the light emitting structures OL-B1, OL-B2, OL-B3, and OL-G may include auxiliary layers TTA-1, TTA-2, TTA-3, and TTA-4 respectively disposed adjacent to the light emitting layers EML-1, EML-2, EML-3, and EML-4. In an embodiment illustrated in FIGS. 9 and 10, the auxiliary layers TTA-1, TTA-2, TTA-3, and TTA-4 may be respectively disposed between the light emitting layers EML-1, EML-2, EML-3, and EML-4 and the electron transport region ETR-1, ETR-2, ETR-3, and ETR-4, and be directly disposed on the light emitting layers EML-1, EML-2, EML-3, and EML-4.

In an embodiment, the auxiliary layers TTA-1, TTA-2, TTA-3, and TTA-4 may each include an anthracene compound represented by Formula 1 or the like, as described with reference to FIGS. 3 to 7. The auxiliary layers TTA-1, TTA-2, TTA-3, and TTA-4 may each independently have a thickness in a range of about 10 Å to about 50 Å. As a film having a small thickness in a range of about 10 Å to about 50 Å includes only the anthracene compound represented by Formula 1 or the like, the fluorescent luminous efficacy of the light emitting element may be increased by utilizing triplet-triplet annihilation between the anthracene compounds.

The auxiliary layers TTA-1, TTA-2, TTA-3, and TTA-4 illustrated in FIG. 10 may be disposed on the light emitting layers EML-1, EML-2, EML-3, and EML-4, respectively, but embodiments are not limited thereto. The auxiliary layers TTA-1, TTA-2, TTA-3, and TTA-4 may respectively be directly disposed below the light emitting layers EML-1, EML-2, EML-3, and EML-4, or may respectively be directly disposed not only on but also below the light emitting layers EML-1, EML-2, EML-3, and EML-4.

In the light emitting element ED-TD according to an embodiment illustrated in FIG. 10, the auxiliary layers TTA-1, TTA-2, TTA-3, and TTA-4 may be respectively included in the light emitting structures OL-B1, OL-B2, OL-B3, and OL-G, but embodiments not limited thereto. At least one of the light emitting structures OL-B1, OL-B2, OL-B3, and OL-G may include the auxiliary layer. For example, a light emitting structure that emits blue light, among the light emitting structures OL-B1, OL-B2, OL-B3, and OL-G, may include the auxiliary layer.

As at least one of the light emitting structures OL-B1, OL-B2, OL-B3, and OL-G includes the auxiliary layer TTA-1, TTA-2, TTA-3 or TTA-4 including the anthracene compound, the fluorescent luminous efficacy may be increased, and thus the light emitting element ED-TD according to an embodiment may exhibit improved luminous efficacy characteristics. As the light emitting element ED-TD which provides source light has the improved efficacy, the display device DD-2 according to an embodiment may exhibit excellent efficacy characteristics and improved display quality.

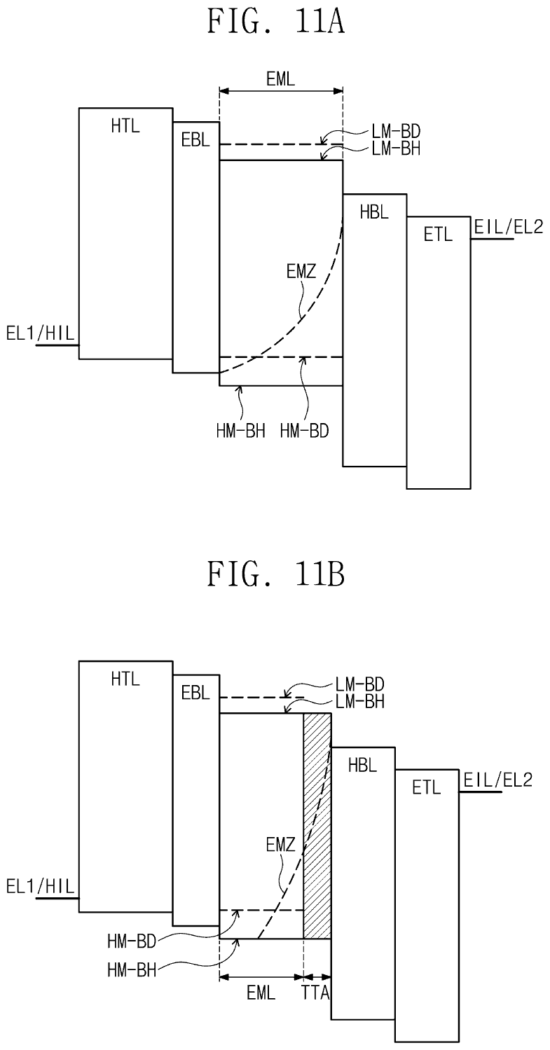

FIGS. 11A and 11B are each a schematic energy level diagram in a light emitting element. FIG. 11A is a schematic energy level diagram of a light emitting element of the related art that does not include an auxiliary layer. FIG. 11B is a schematic energy level diagram of a light emitting element according to an embodiment that includes an auxiliary layer.

In the energy level diagrams shown in FIGS. 11A and 11B, the light emitting elements may each include a first electrode EL1, a hole injection layer HIL, a hole transport layer HTL, an electron blocking layer EBL, a light emitting layer EML, a hole blocking layer HBL, an electron transport layer ETL, an electron injection layer EIL, and a second electrode EL2 which are stacked in that order. The light emitting layer EML may include a host and a dopant. In an embodiment, the light emitting element may differ from a light emitting element of the related art in that the light emitting element may include an auxiliary layer TTA between the light emitting layer EML and the hole blocking layer HBL.

In an embodiment, the auxiliary layer TTA may include an anthracene compound represented by Formula 1 or the like, as described above. The auxiliary layer TTA may include only the anthracene compound but may not include a dopant. For example, the auxiliary layer TTA may consist of the anthracene compound. The auxiliary layer TTA may include only one kind of the anthracene compound represented by Formula 1 or the like. The auxiliary layer TTA may have a relatively small layer thickness compared to the light emitting layer EML. A thickness of the light emitting layer EML in the light emitting element of the related art illustrated in FIG. 11A may be similar to a sum of a thickness of the light emitting layer EML and a thickness of the auxiliary layer TTA in the light emitting element according to an embodiment illustrated in FIG. 11B. A density of the anthracene compound in the auxiliary layer TTA may be higher than a density of host materials in the light emitting layer EML.

In FIGS. 11A and 11B, HM-BH indicates a highest occupied molecular orbital (HOMO) energy level of the host included in the light emitting layer EML, and HM-BD indicates a HOMO energy level of the dopant included in the light emitting layer EML. LM-BH indicates a lowest unoccupied molecular orbital (LUMO) energy level of the host included in the light emitting layer EML, and LM-BD indicates a LUMO energy level of the dopant included in the light emitting layer EML.

In FIGS. 11A and 11B, EMZ indicates an exciton emission zone. In the light emitting element of the related art illustrated in FIG. 11A, the EMZ is shown broadly in the entire area of the light emitting layer EML. In the light emitting element according to an embodiment illustrated in FIG. 11B, as the auxiliary layer TTA shows high exciton density, the EMZ is biased to the auxiliary layer TTA and has a distribution in a relatively narrow area.

Referring to FIGS. 11A and 11B, in comparison to the light emitting element of the related art that does not include the auxiliary layer TTA, in the light emitting element including the auxiliary layer TTA, formation of singlet excitons by triplet-triplet annihilation occurs quickly and intensively in the auxiliary layer TTA and the area of the light emitting layer EML adjacent thereto. Accordingly, in the light emitting element according to an embodiment, the fluorescent luminous efficacy of the light emitting layer EML is increased. In comparison, in the light emitting element of the related art that does not include the auxiliary layer TTA, the host materials are broadly distributed in the light emitting layer EML. Thus, the probability of the triplet-triplet annihilation is decreased, and accordingly, generation of singlet excitons by triplet-triplet annihilation may not be achieved.

FIGS. 11A and 11B illustrate the configuration of the light emitting element in which the EMZ has exciton distribution increasing from the light emitting layer EML toward the electron transport region ETR, but embodiments are not limited thereto. In an embodiment, according to material combinations of the hole transport region HTR, the light emitting layer EML, and the electron transport region ETR, the light emitting element having a configuration in which the EMZ has exciton distribution increasing from the light emitting layer EML toward the hole transport region HTR may be provided. In an embodiment, the auxiliary layer may be disposed between the hole transport region HTR and the light emitting layer EML.

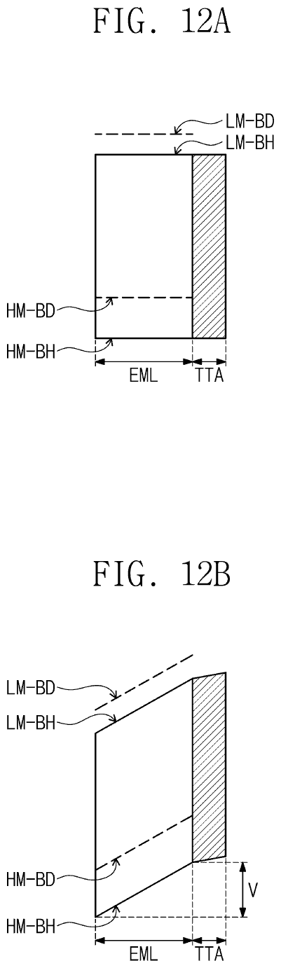

FIGS. 12A and 12B are each a schematic diagram of an operation of a light emitting element according to an embodiment including an auxiliary layer. FIGS. 12A and 12B each illustrate only an energy diagram in a light emitting layer EML and an auxiliary layer TTA disposed adjacent thereto in the light emitting element. FIG. 12A illustrates an energy level of the light emitting element before being driven, and FIG. 12B illustrates an energy level of the light emitting element after being driven. In FIGS. 12A and 12B, HM-BH indicates HOMO energy level of the host included in the light emitting layer EML, and HM-BD indicates a HOMO energy level of the dopant included in the light emitting layer EML. LM-BH indicates LUMO energy level of the host included in the light emitting layer EML, and LM-BD indicates a LUMO energy level of the dopant included in the light emitting layer EML.

In an embodiment, a difference in energy level, i.e., potential difference, in the light emitting element may be expressed as Equation 1.

$$V = \frac{v}{μ} l \qquad [ Equation 1 ]$$

In Equation 1, V indicates a potential difference, indicates a mobility, ν indicates a drift velocity, and l indicates a layer thickness.

The potential difference is generated in a light emitting layer EML by driving the light emitting element. In the light emitting layer EML including a host and a dopant, as the dopant works as a trap, a mobility (μ) of molecules in the light emitting layer EML doped with the dopant is lower than a mobility (μ) of molecules in an auxiliary layer TTA without the dopant.

Accordingly, a potential difference (V) in the light emitting layer EML is high, and a potential difference (V) in the auxiliary layer TTA is low. Thus, formation of excitons by triplet-triplet annihilation may readily occur in the auxiliary layer TTA, and a singlet exciton generated in the auxiliary layer TTA may be readily transferred to a neighboring light emitting layer EML. The singlet exciton generated in the auxiliary layer TTA may transfer energy to the dopant (Förster energy transfer). Accordingly, the luminous efficacy of the light emitting layer EML may be increased.

Hereinafter, a light emitting element according to an embodiment will be described in detail with reference to the Examples and the Comparative Examples. The Examples described below are only provided to facilitate in understanding the disclosure, and the scope thereof is not limited thereto.

### Examples and Comparative Examples

### <Manufacture of Light Emitting Elements>

Light emitting elements of Examples and Comparative Examples were manufactured using the following methods. Comparative Examples 1-1 and 1-2, and Examples 1-1 to 1-3 of a light emitting element 1 correspond to a case of having the structure of the light emitting element shown in FIG. 4. In the light emitting element 1, a first electrode is a transmissive/semi-transmissive electrode, and a second electrode is a reflective electrode. Thus, the light emitting element 1 has a bottom emission-type structure.

ITO was provided on a glass substrate to form the first electrode, and the glass substrate on which an ITO layer was formed was disposed in a vacuum chamber to form a hole transport region, a light emitting layer, an auxiliary layer, an electron transport region, and a second electrode in sequence. The hole transport region was formed to include a hole injection layer, a hole transport layer, and an electron blocking layer, stacked in sequence. The hole injection layer had a thickness of about 50 Å, the hole transport layer had a thickness of about 600 Å, and the electron blocking layer had a thickness of about 90 Å. The hole injection layer was formed using HATCN, as shown below in the section subtitled “Materials used in Manufacture of Light Emitting Elements”. The hole transport layer was formed using NPB, and the electron blocking layer was formed using TCTA.

The light emitting layer was formed on the hole transport region to have a thickness of about 150 Å, and the auxiliary layer was formed on the light emitting layer to have a thickness of about 30 Å.

The electron transport region was formed to include a hole blocking layer, an electron transport layer, and an electron injection layer, stacked in sequence. The hole blocking layer had a thickness of about 50 Å, the electron transport layer had a thickness of about 250 Å, and the electron injection layer had a thickness of about 11 Å. Yb was deposited to form the electron injection layer. Ag and Mg were deposited at a weight ratio of about 95:5 to form the second electrode having a thickness of about 1,000 Å, so as to complete the manufacture of the first light emitting element of Example 1-1. The hole blocking layer was formed using TPBi, and the electron transport layer was formed using Bphen.

Comparative Example 2, and Examples 2-1 and 2-2 of a light emitting element 2 correspond to a case of having the structure of the light emitting element shown in FIG. 10. The light emitting element 2 has a top emission-type structure.

An Ag layer was formed on a glass substrate to have a sufficient thickness to the extent that visible light is not allowed to be transmitted. An ITO layer was provided on the Ag layer to form the first electrode. First to fourth light emitting structures were formed in sequence on the first electrode. Charge generation layers were each formed between the light emitting structures.

The first light emitting structure, a first charge generation layer, the second light emitting structure, a second charge generation layer, the third light emitting structure, a third charge generation layer, and the fourth light emitting structure were formed in sequence on the first electrode. The first to third light emitting structures were formed as blue light emitting structures, and the fourth light emitting structure was formed as a green light emitting structure.

The first light emitting structure was formed to include, as a hole transport region, a hole injection layer having a thickness of about 50 Å, a hole transport layer having a thickness of about 250 Å, and an electron blocking layer having a thickness of about 90 Å, and to include a light emitting layer having a thickness of about 150 Å and an auxiliary layer having a thickness of about 30 Å. An electron transport region disposed on the auxiliary layer was formed to include a hole blocking layer having a thickness of about 50 Å and an electron transport layer having a thickness of about 100 Å.

The second light emitting structure was formed to include, as a hole transport region, a hole transport layer having a thickness of about 700 Å and an electron blocking layer having a thickness of about 90 Å, and to include a light emitting layer having a thickness of about 150 Å and an auxiliary layer having a thickness of about 30 Å. An electron transport region disposed on the auxiliary layer was formed to include a hole blocking layer having a thickness of about 50 Å and an electron transport layer having a thickness of about 100 Å.

The third light emitting structure was formed to include, as a hole transport region, a hole transport layer having a thickness of about 500 Å and an electron blocking layer having a thickness of about 90 Å, and to include a light emitting layer having a thickness of about 150 Å and an auxiliary layer having a thickness of about 30 Å. An electron transport region disposed on the auxiliary layer was formed to include a hole blocking layer having a thickness of about 50 Å and an electron transport layer having a thickness of about 100 Å.

The first to third light emitting structures are blue light emitting structures, and may have the same light emitting layer and auxiliary layer material compositions as the light emitting element 1 described above.

The fourth light emitting structure was formed to include a hole transport layer having a thickness of about 320 Å as a hole transport region, a light emitting layer having a thickness of about 420 Å, an auxiliary layer having a thickness of about 30 Å, and an electron transport layer having a thickness of about 100 Å as an electron transport region. In the fourth light emitting structure, the light emitting layer was formed to include a green hole transport layer host (G-HT host), a green electron transport layer host (G-ET host), and a green dopant (G dopant) at a weight ratio of about 45:45:10. In the fourth light emitting structure, the electron transport layer was formed by depositing a green electron transport layer material (G-ETL) and Liq at a weight ratio of about 5:5.

The first to third charge generation layers were each formed to include a stacked structure of an n-type charge generation layer and a p-type charge generation layer. The n-type charge generation layer was formed by depositing Bphen:Yb at a weight ratio of about 99:1, and the p-type charge generation layer was formed by depositing NPB:HATCN at a weight ratio of about 9:1. In each of the first to third charge generation layers, the n-type charge generation layer had a thickness of about 40 Å, and the p-type charge generation layer had a thickness of about 70 Å.

An electron injection layer, a second electrode, and a capping layer were formed in sequence on the fourth light emitting structure. The electron injection layer was formed to include Yb and have a thickness of about 11 Å. The second electrode was formed on the electron injection layer to have a thickness of about 100 Å. Ag:Mg were co-deposited at a weight ratio of about 95:5 to form the second electrode. NPB was deposited on the second electrode to form the capping layer having a thickness of about 600 Å.

The materials used in the manufacture of the light emitting element 1 and the light emitting element 2 are as follows. The materials used for the hole injection layer, hole transport layer, electron blocking layer, hole blocking layer, and electron transport layer in the second light emitting element are the same as those used in the first light emitting element.

### (Materials Used in Manufacture of Light Emitting Elements)

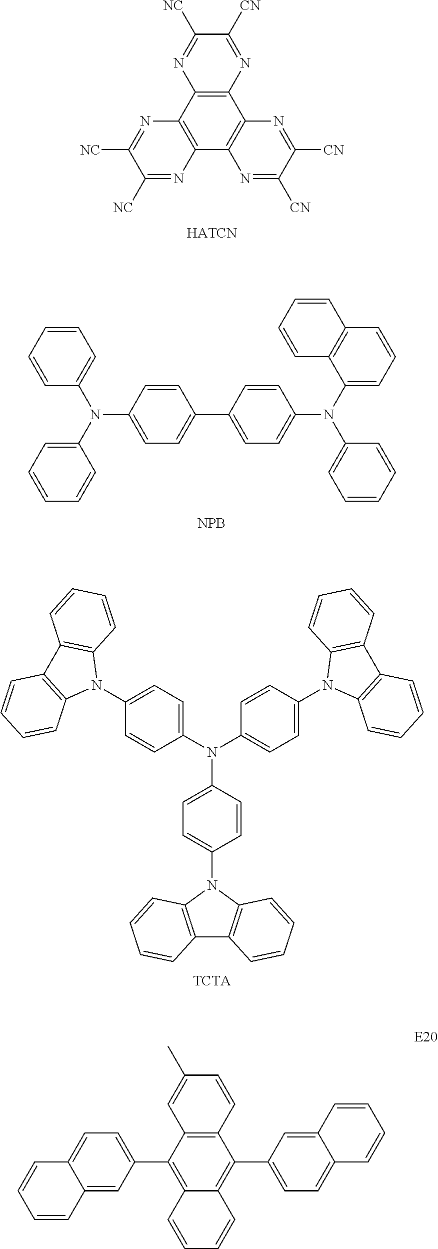

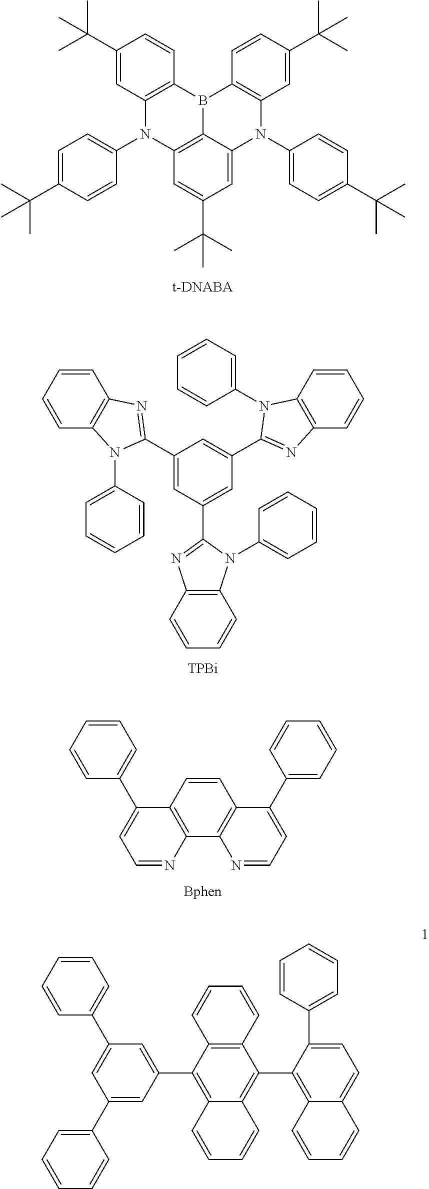

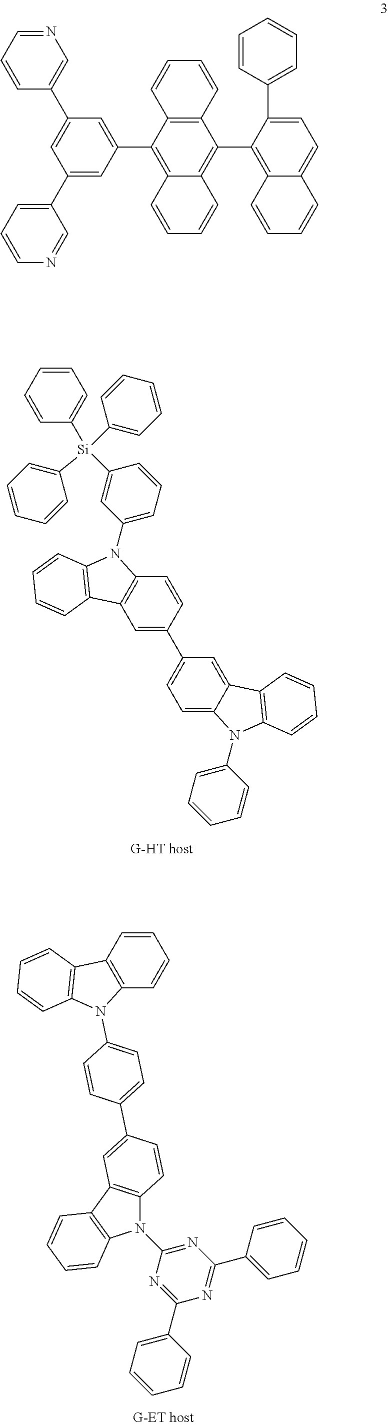 [SMILES: c1ccc(-c2ccc3ccccc3c2-c2c3ccccc3c(-c3cc(-c4cccnc4)cc(-c4cccnc4)c3)c3ccccc23)cc1 ; c1ccc(-n2c3ccccc3c3cc(-c4ccc5c(c4)c4ccccc4n5-c4cccc([Si](c5ccccc5)(c5ccccc5)c5ccccc5)c4)ccc32)cc1 ; c1ccc(-c2nc(-c3ccccc3)nc(-n3c4ccccc4c4cc(-c5ccc(-n6c7ccccc7c7ccccc76)cc5)ccc43)n2)cc1]

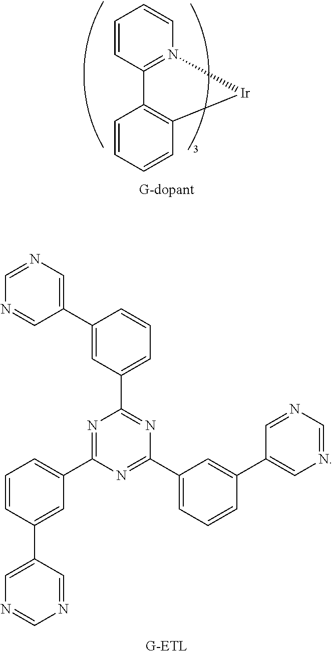

### <Evaluation of Light Emitting Elements>

Tables 1 and 2 show evaluation results for the light emitting elements of the Examples and the Comparative Examples. Table 1 shows the evaluation results for the Examples and the Comparative Examples each having the structure of the light emitting element 1 described above. Table 2 shows the evaluation results for the Examples and the Comparative Examples each having the structure of the light emitting element 2 described above.

Tables 1 and 2 show driving voltage, total radiative exciton ratio, efficacy, power efficacy, and lifespan with respect to the light emitting elements of the Examples and the Comparative Examples.

In Table 1, in Comparative Example 1-1, a light emitting layer was manufactured to include a host and a dopant and have a thickness of about 180 Å. In Comparative Example 1-2, a light emitting layer was manufactured to include a host and a dopant and have a thickness of about 150 Å, and an auxiliary layer was formed on the light emitting layer to have a thickness of about 30 Å. The auxiliary layer in Comparative Example 1-2 was formed to include MADN. In Example 1-1, Compound 1 was used for an auxiliary layer, and in Examples 1-2 and 1-3, Compound 3 was used for an auxiliary layer.

The evaluation results for the light emitting element 1 shown in Table 1 are results obtained by evaluating current and luminance measured by varying voltages provided to the light emitting element. Comparison of the current efficacy and the power efficacy at a luminance of about 1500 cd/m² are shown, and the lifespan was evaluated by applying constant current to exhibit a luminance of about 1500 cd/m² and measuring a luminance change accordingly. In the lifespan, a time period for which the luminance reaches a level of about 95% of an initial luminance was evaluated.

In Table 1, the driving voltage, the total radiative exciton ratio, the efficacy, the power efficacy, and the lifespan are each expressed as a relative value based on 100% of an evaluation value for Comparative Example 1-1.

TABLE 1

| | | | Total | | | |
|---|---|---|---|---|---|---|
| | | Driving | radiative | | Power | Lifespan |
| Category | Stack Structure | voltage | exciton ratio | Efficacy | efficacy | (LT95) |
| Comparative | Light emitting layer (180 Å) | 100% | 100% | 100% | 100% | 100% |
| Example 1-1 | | | | | | |
| Comparative | Light emitting layer (150 Å)/ | 99% | 100% | 100% | 99% | 98% |
| Example 1-2 | Auxiliary layer (30 Å) | | | | | |
| Example 1-1 | Light emitting layer (150 Å)/ | 94% | 113% | 111% | 118% | 133% |
| | Auxiliary layer (30 Å) | | | | | |
| Example 1-2 | Light emitting layer (130 Å)/ | 89% | 106% | 103% | 116% | 105% |
| | Auxiliary layer (50 Å) | | | | | |
| Example 1-3 | Light emitting layer (150 Å)/ | 101% | 110% | 108% | 107% | 121% |
| | Auxiliary layer (30 Å) | | | | | |

In Examples 1-1 to 1-3, compared to Comparative Example 1-1, all the total radiative exciton ratio, the efficacy, and the power efficacy were increased, and in terms of the lifespan, improved characteristics were exhibited. In Examples 1-1 to 1-3, even compared to Comparative Example 1-2, all the total radiative exciton ratio, the efficacy, and the power efficacy were increased, and in terms of the lifespan, improved characteristics were exhibited. For example, the light emitting element according to an embodiment includes the auxiliary layer disposed adjacent to the light emitting layer and including the compound having the anthracene core, thereby exhibiting characteristics that the radiative exciton ratio, the luminous efficacy, and the lifespan are improved. In Table 2, in Comparative Example 2-1, a light emitting layer was manufactured to include a host and a dopant and have a thickness of about 180 Å. In Comparative Example 2-2, a light emitting layer was manufactured to include a host and a dopant and have a thickness of about 150 Å, and an auxiliary layer was formed on the light emitting layer to have a thickness of about 30 Å. The auxiliary layer in Comparative Example 2-2 was formed to include MADN. In Example 2-1, Compound 1 was used for an auxiliary layer, and in Examples 2-2 and 2-3, Compound 3 was used for an auxiliary layer.

The evaluation results for the light emitting element 2 shown in Table 2 are results obtained by comparing efficacies and lifespans of the light emitting element at a current density of about 10 mA/cm². In the lifespan, a time period for which the luminance reaches a level of about 95% of an initial luminance was evaluated. In Table 2, driving voltage, efficacy, power efficacy, and lifespan are each expressed as a relative value based on 100% of an evaluation value for Comparative Example 2-1.

TABLE 2

| | Stack | Driving | | Power | Lifespan |
|---|---|---|---|---|---|
| Category | structure | voltage | Efficacy | efficacy | (LT95) |
| Comparative | Light emitting layer (180 Å) | 100% | 100% | 100% | 100% |
| Example 2-1 | | | | | |
| Comparative | Light emitting layer (150 Å)/ | 98% | 100% | 102% | 100% |
| Example 2-2 | Auxiliary layer (30 Å) | | | | |
| Example 2-1 | Light emitting layer (150 Å)/ | 96% | 107% | 112% | 128% |
| | Auxiliary layer (30 Å) | | | | |
| Example 2-2 | Light emitting layer (130 Å)/ | 93% | 102% | 110% | 105% |
| | Auxiliary layer (50 Å) | | | | |
| Example 2-3 | Light emitting layer (150 Å)/ | 103% | 105% | 102% | 117% |
| | Auxiliary layer (30 Å) | | | | |

In Examples 2-1 to 2-3, compared to Comparative Example 2-1, both the efficacy and the power efficacy were increased, and in terms of the lifespan, improved characteristics were exhibited. In Examples 2-1 to 2-3, even compared to Comparative Example 2-2, both the efficacy and the power efficacy were increased, and in terms of the lifespan, improved characteristics were exhibited. For example, the light emitting element according to an embodiment includes the auxiliary layer disposed adjacent to the light emitting layer and including the compound having the anthracene core, thereby exhibiting characteristics that the radiative exciton ratio and the luminous efficacy are improved.

The light emitting element according to an embodiment may include the auxiliary layer disposed at least one of above or below the light emitting layer and including the anthracene compound having the anthracene core, and thus induce generation of singlet excitons by triplet-triplet annihilation between the anthracene compounds in the auxiliary layer, thereby exhibiting characteristics that the fluorescent luminous efficacy is increased.

The light emitting element according to an embodiment may include the auxiliary layer disposed adjacent to the light emitting layer, which provides the source light, and including the anthracene compound, and thus the fluorescent luminous efficacy of the light emitting layer may be increased to exhibit high luminance and high photoconversion efficacy. Accordingly, the display device according to an embodiment may exhibit improved display quality characteristics.

The light emitting element according to an embodiment may include the auxiliary layer disposed adjacent to the light emitting layer and including only the anthracene compound, thereby exhibiting high efficacy characteristics.

The display device according to an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a hole transport region disposed on the first electrode;
a light emitting layer disposed on the hole transport region;
an electron transport region disposed on the light emitting layer;
a second electrode disposed on the electron transport region; and
an auxiliary layer disposed between at least one of the hole transport region and the light emitting layer or the light emitting layer and the electron transport region, wherein
the auxiliary layer comprises an anthracene compound represented by Formula 1: 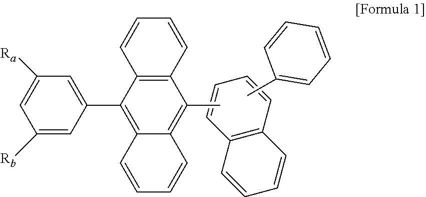
wherein in Formula 1,
Rₐ and R_{b} are each independently a group represented by Formula 2: 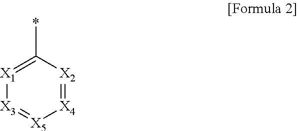
wherein in Formula 2,
X₁ to X₅ are each independently N or CH.

2. The light emitting element of claim 1, wherein the auxiliary layer is disposed directly between the light emitting layer and the electron transport region.

3. The light emitting element of claim 1,
wherein the electron transport region comprises:
a hole blocking layer disposed on the light emitting layer;
an electron transport layer disposed on the hole blocking layer; and
an electron injection layer disposed on the electron transport layer, and
the auxiliary layer is disposed directly between the light emitting layer and the hole blocking layer.

4. The light emitting element of claim 1, wherein the auxiliary layer is disposed directly between the light emitting layer and the hole transport region.

5. The light emitting element of claim 1, wherein the anthracene compound is represented by one of Formulae 1-1 to 1-6: 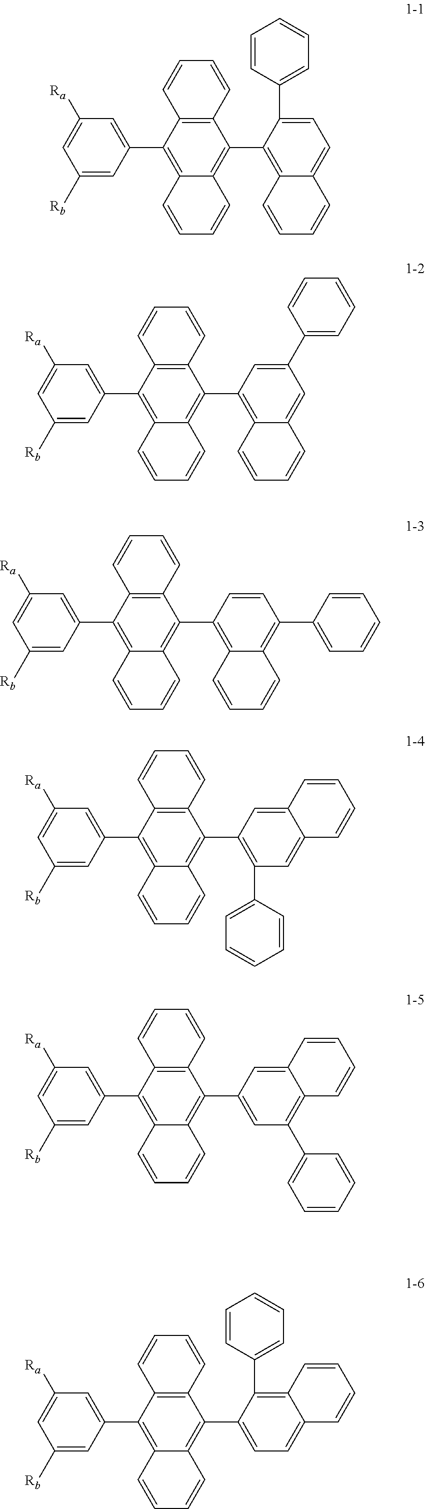
wherein in Formulae 1-1 to 1-6,
Rₐ and R_{b} are each the same as defined in Formula 1.

6. The light emitting element of claim 1, wherein the group represented by Formula 2 is a group represented by one of Formulae 2a to 2h:

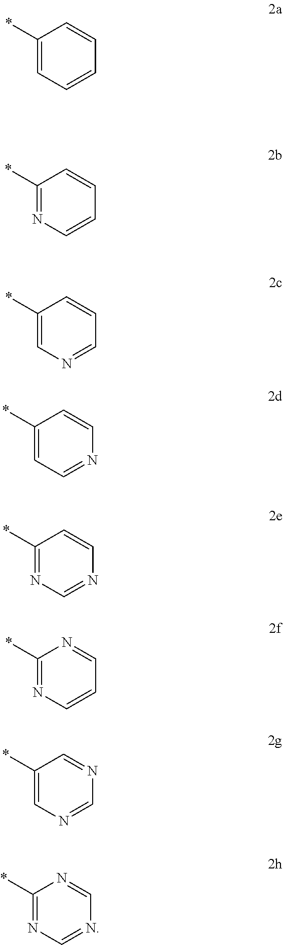

7. The light emitting element of claim 1, wherein the anthracene compound is selected from Compound Group 1:

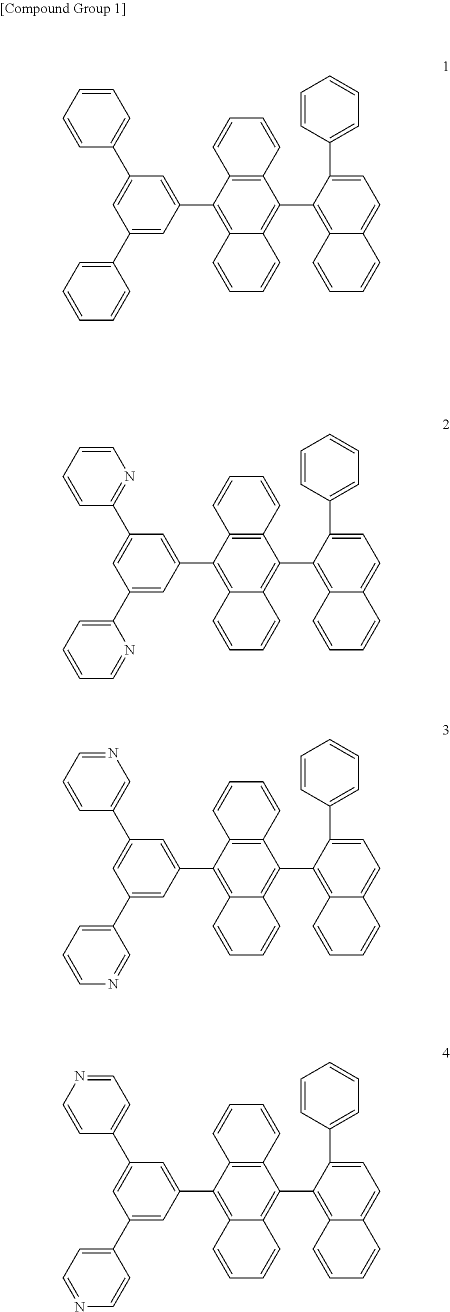

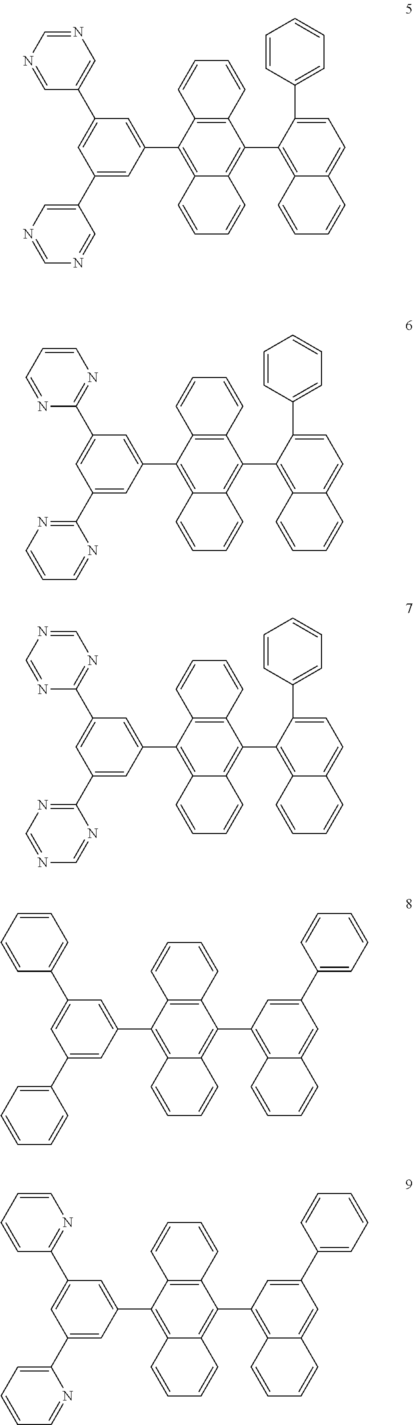

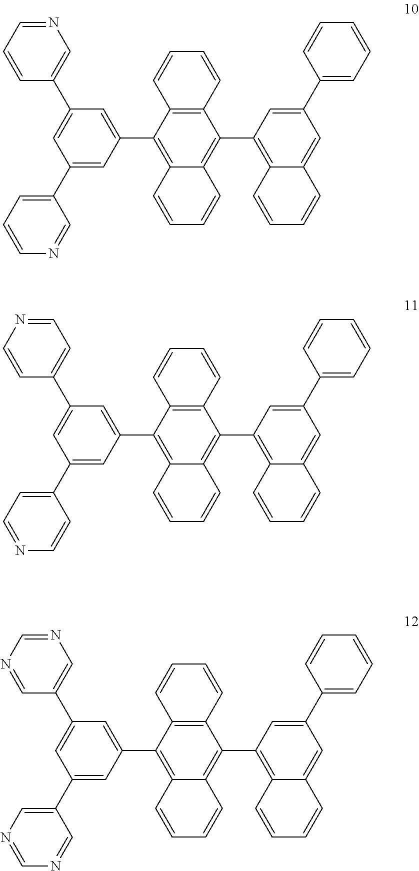 [SMILES: c1ccc(-c2cc(-c3c4ccccc4c(-c4cc(-c5cccnc5)cc(-c5cccnc5)c4)c4ccccc34)c3ccccc3c2)cc1 ; c1ccc(-c2cc(-c3c4ccccc4c(-c4cc(-c5ccncc5)cc(-c5ccncc5)c4)c4ccccc34)c3ccccc3c2)cc1 ; c1ccc(-c2cc(-c3c4ccccc4c(-c4cc(-c5cncnc5)cc(-c5cncnc5)c4)c4ccccc34)c3ccccc3c2)cc1]

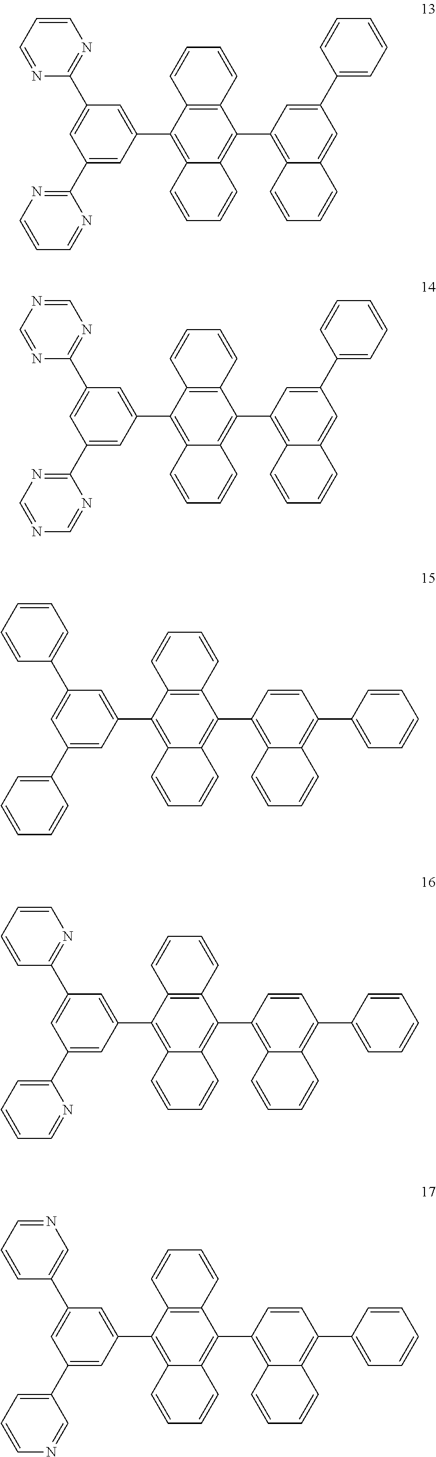

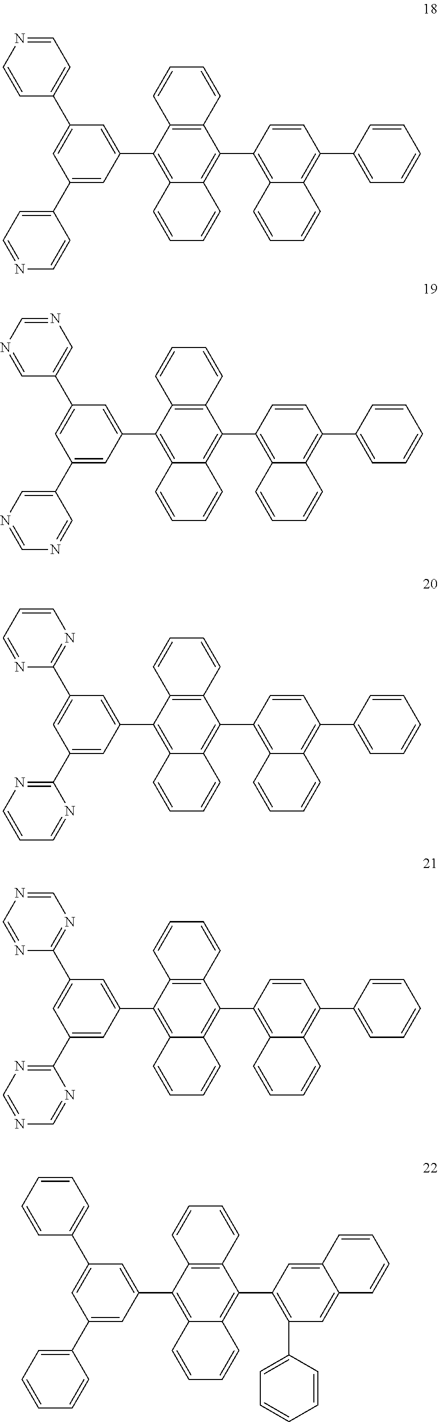

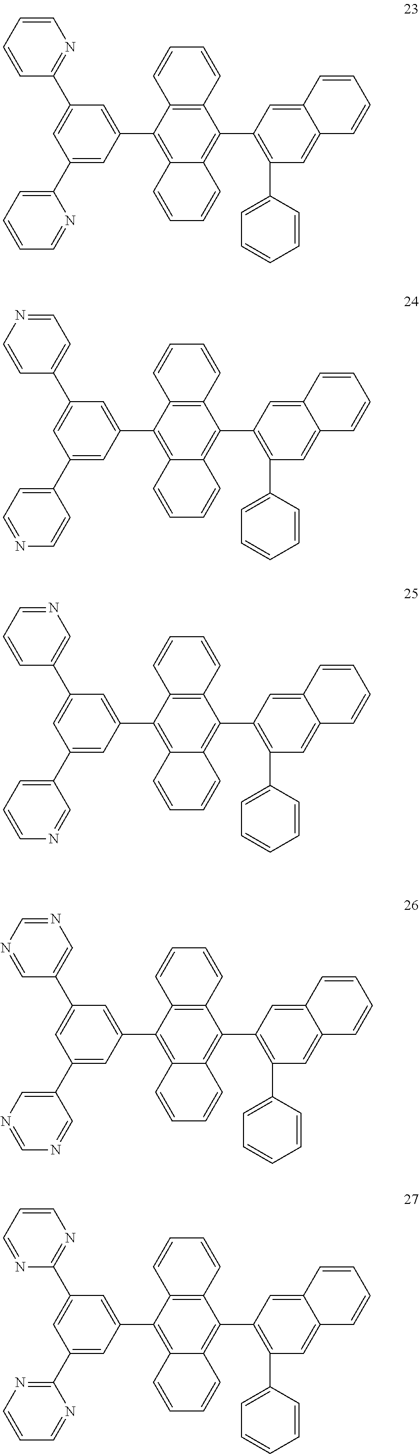 [SMILES: c1ccc(-c2cc3ccccc3cc2-c2c3ccccc3c(-c3cc(-c4ccccn4)cc(-c4ccccn4)c3)c3ccccc23)cc1 ; c1ccc(-c2cc3ccccc3cc2-c2c3ccccc3c(-c3cc(-c4ccncc4)cc(-c4ccncc4)c3)c3ccccc23)cc1 ; c1ccc(-c2cc3ccccc3cc2-c2c3ccccc3c(-c3cc(-c4cccnc4)cc(-c4cccnc4)c3)c3ccccc23)cc1 ; c1ccc(-c2cc3ccccc3cc2-c2c3ccccc3c(-c3cc(-c4cncnc4)cc(-c4cncnc4)c3)c3ccccc23)cc1 ; c1ccc(-c2cc3ccccc3cc2-c2c3ccccc3c(-c3cc(-c4ncccn4)cc(-c4ncccn4)c3)c3ccccc23)cc1]

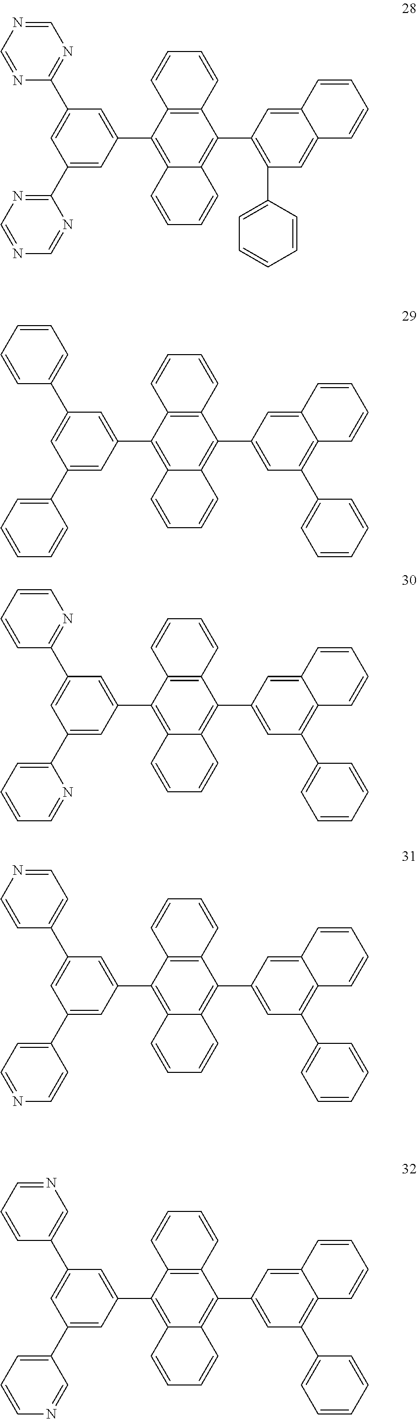

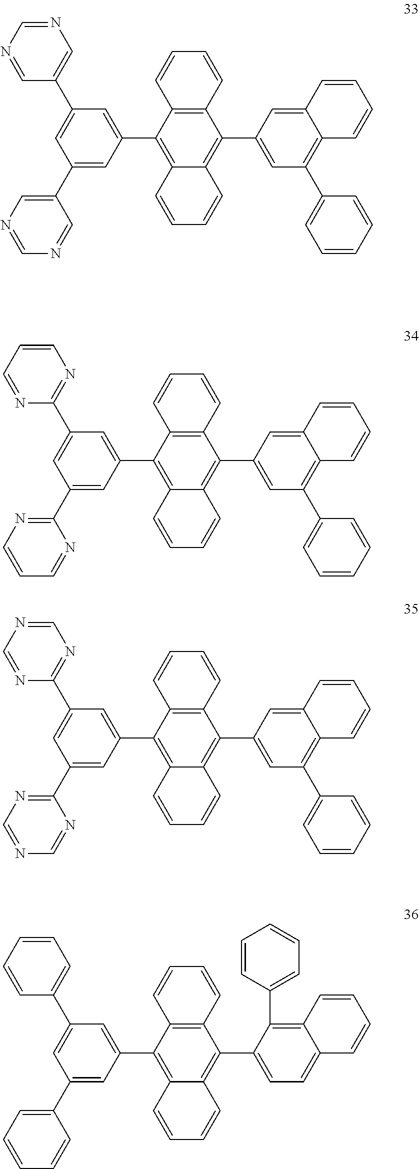

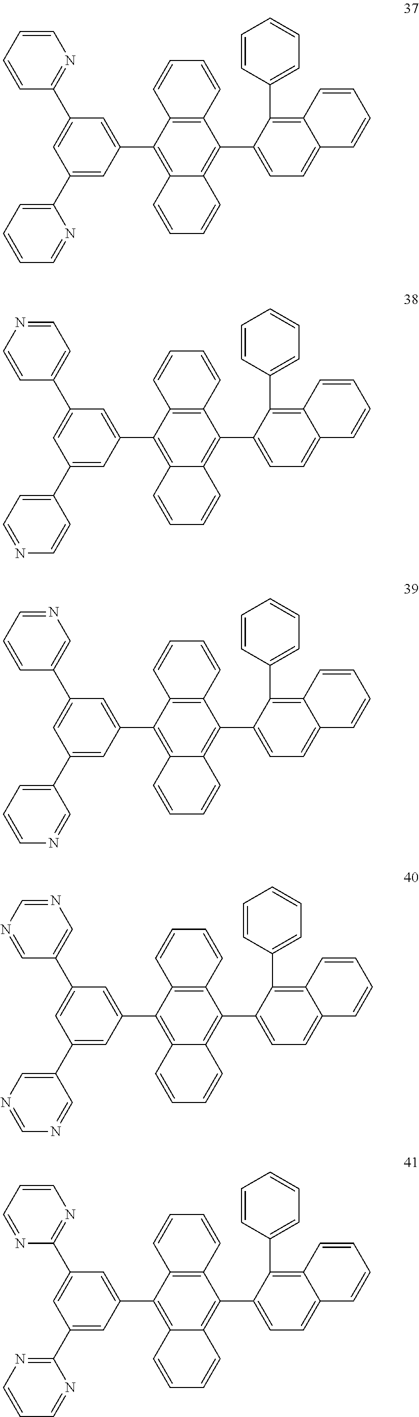 [SMILES: c1ccc(-c2c(-c3c4ccccc4c(-c4cc(-c5ccccn5)cc(-c5ccccn5)c4)c4ccccc34)ccc3ccccc23)cc1 ; c1ccc(-c2c(-c3c4ccccc4c(-c4cc(-c5ccncc5)cc(-c5ccncc5)c4)c4ccccc34)ccc3ccccc23)cc1 ; c1ccc(-c2c(-c3c4ccccc4c(-c4cc(-c5cccnc5)cc(-c5cccnc5)c4)c4ccccc34)ccc3ccccc23)cc1 ; c1ccc(-c2c(-c3c4ccccc4c(-c4cc(-c5cncnc5)cc(-c5cncnc5)c4)c4ccccc34)ccc3ccccc23)cc1 ; c1ccc(-c2c(-c3c4ccccc4c(-c4cc(-c5ncccn5)cc(-c5ncccn5)c4)c4ccccc34)ccc3ccccc23)cc1]

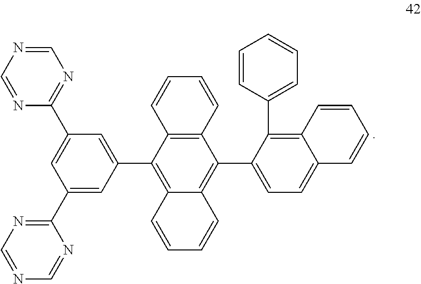 [SMILES: c1ccc(-c2c(-c3c4ccccc4c(-c4cc(-c5ncncn5)cc(-c5ncncn5)c4)c4ccccc34)ccc3ccccc23)cc1]

8. The light emitting element of claim 1, wherein
the light emitting layer has a thickness in a range of about 50 Å to about 200 Å, and
the auxiliary layer has a thickness in a range of about 10 Å to about 50 Å.

9. The light emitting element of claim 1, wherein
the light emitting layer comprises a host, and a blue dopant having a maximum emission peak in a range of about 400 nm to about 450 nm, and
the auxiliary layer does not comprise a dopant but comprises the anthracene compound.

10. A light emitting element comprising:
a first electrode;
a second electrode facing the first electrode; and
at least one light emitting structure disposed between the first electrode and the second electrode, wherein
the at least one light emitting structure comprises:
a hole transport region;
a light emitting layer disposed on the hole transport region;
an electron transport region disposed on the light emitting layer; and
an auxiliary layer disposed directly above and/or directly below the light emitting layer, and
the auxiliary layer comprises an anthracene compound represented by Formula 1: 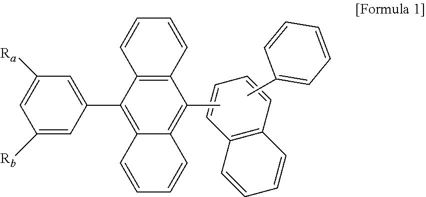
wherein in Formula 1,
Rₐ and R_{b} are each independently a group represented by Formula 2: 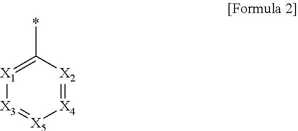
wherein in Formula 2,
X₁ to X₅ are each independently N or CH.

11. The light emitting element of claim 10, wherein
the light emitting element includes a plurality of light emitting structures, and
the light emitting element further comprises a charge generation layer between adjacent structures among the plurality of light emitting structures.

12. The light emitting element of claim 11, wherein the plurality of light emitting structures comprise:
a first light emitting structure disposed on the first electrode and that emits blue light;
a second light emitting structure disposed on the first light emitting structure and that emits blue light;
a third light emitting structure disposed on the second light emitting structure and that emits blue light; and
a fourth light emitting structure disposed on the third light emitting structure and that emits green light.

13. The light emitting element of claim 10, wherein
the electron transport region comprises:
a hole blocking layer;
an electron transport layer; and
an electron injection layer,
the hole blocking layer, the electron transport layer, and the electron injection layer are sequentially stacked in a thickness direction, and
the auxiliary layer is disposed directly between the light emitting layer and the hole blocking layer.

14. The light emitting element of claim 10, wherein the anthracene compound is selected from Compound Group 1:

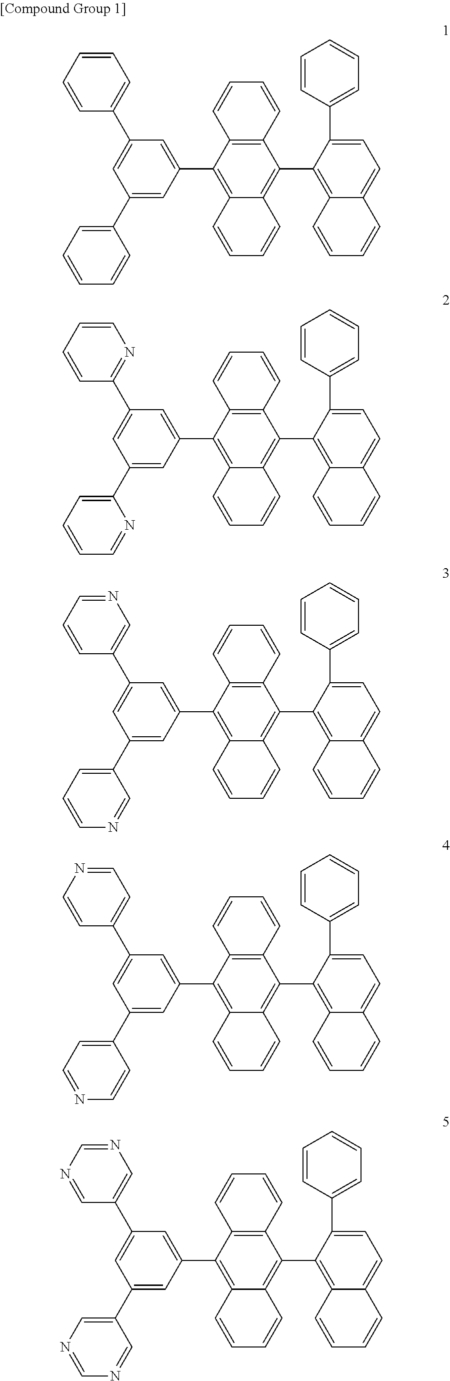

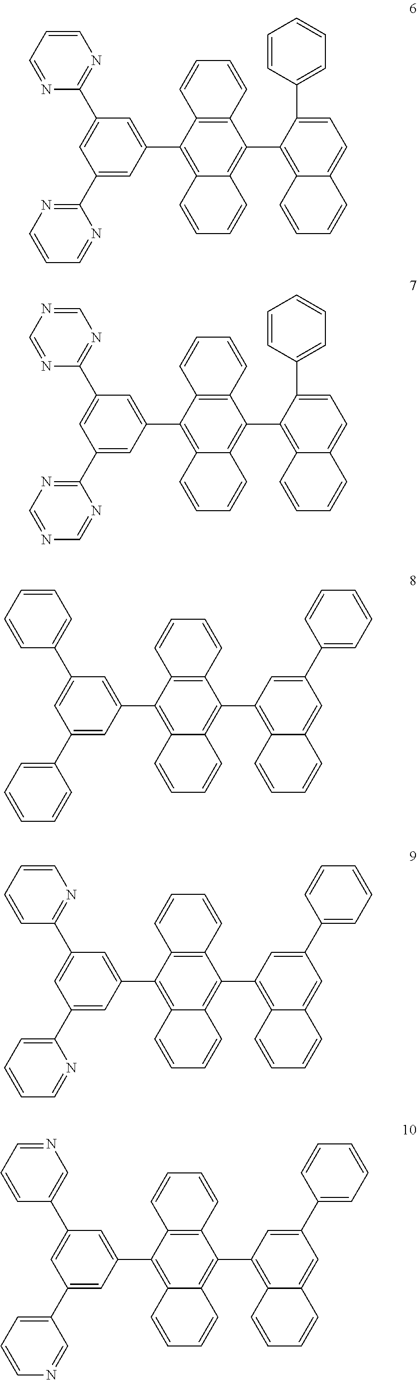

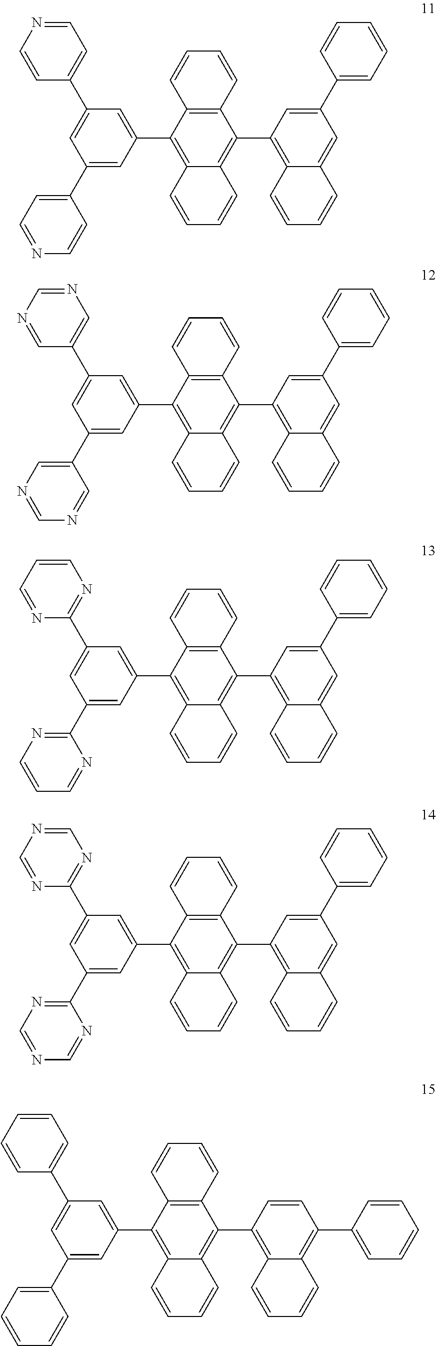

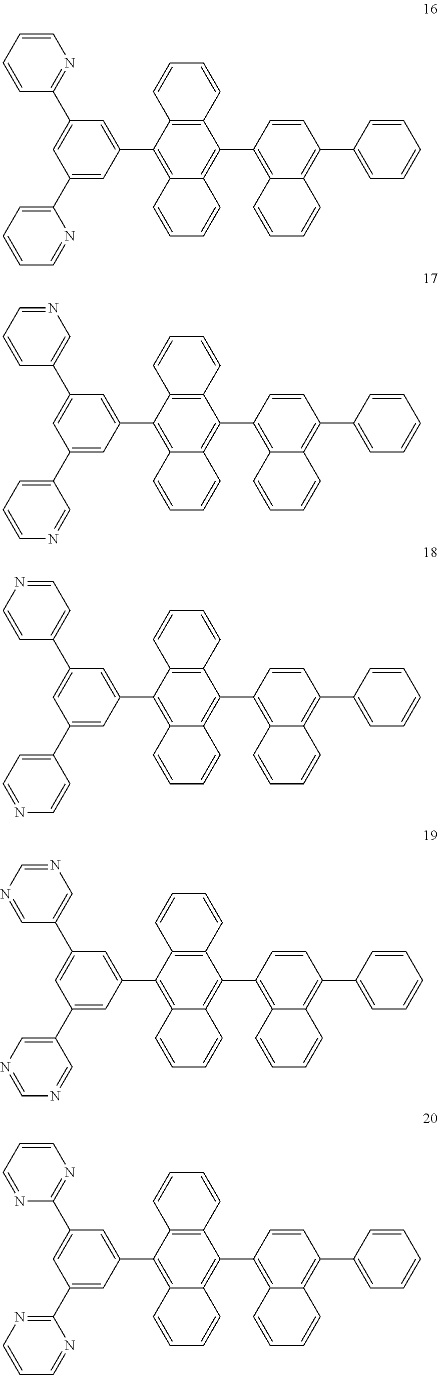

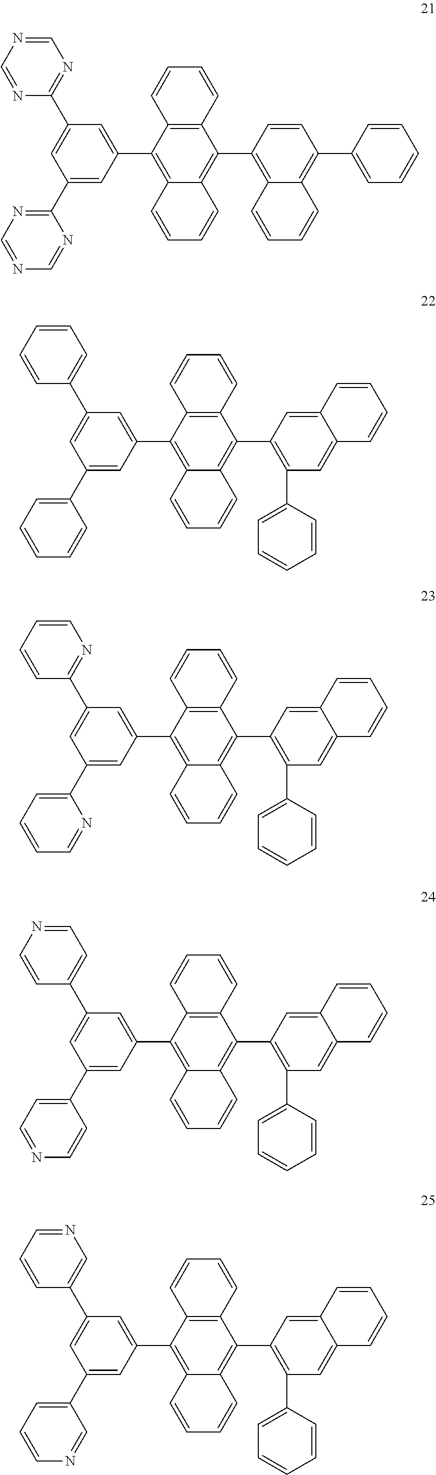

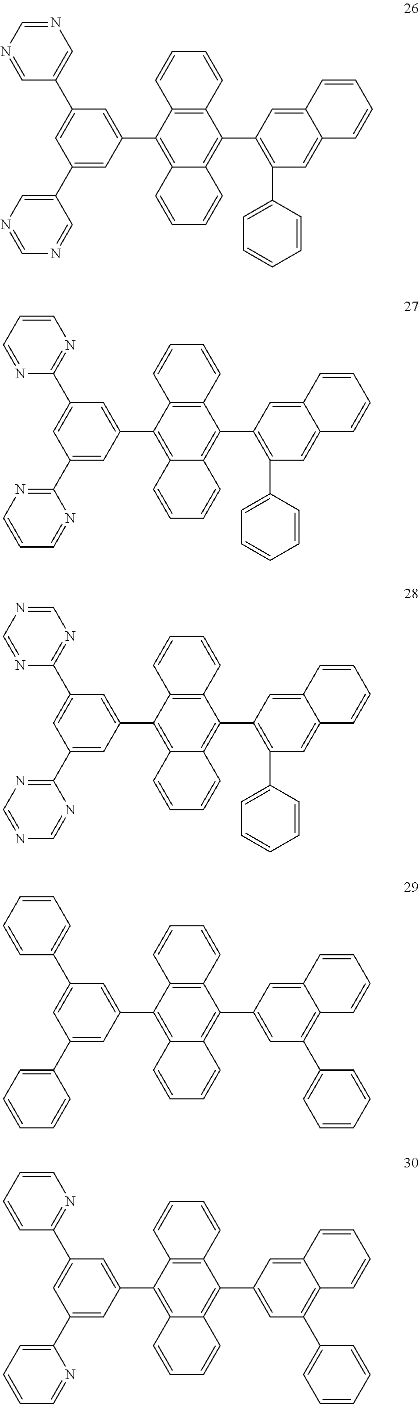

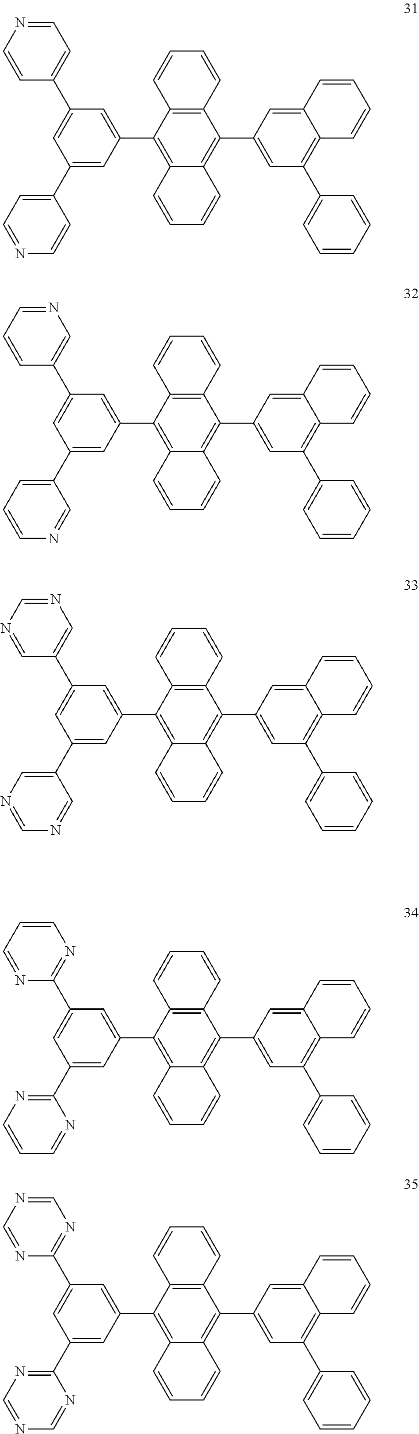

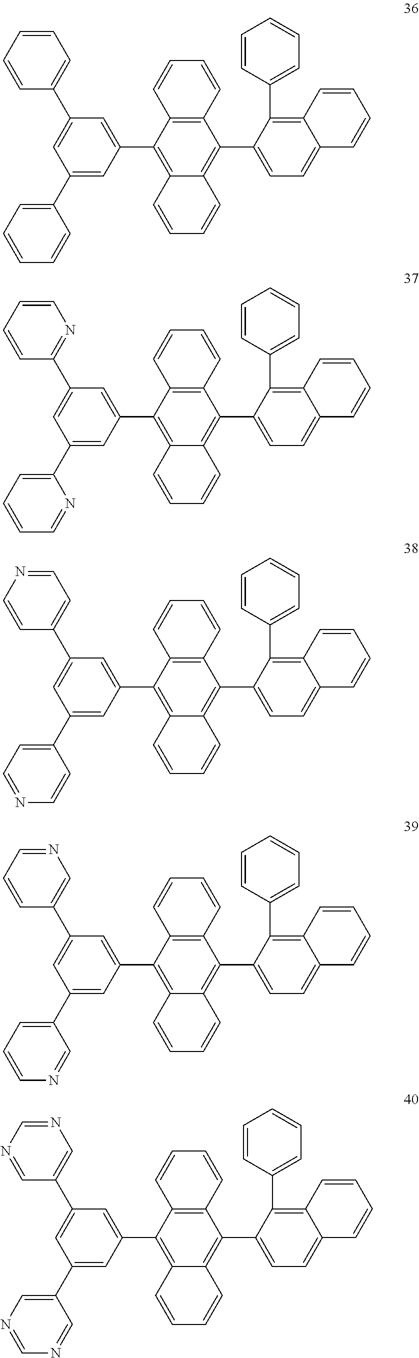

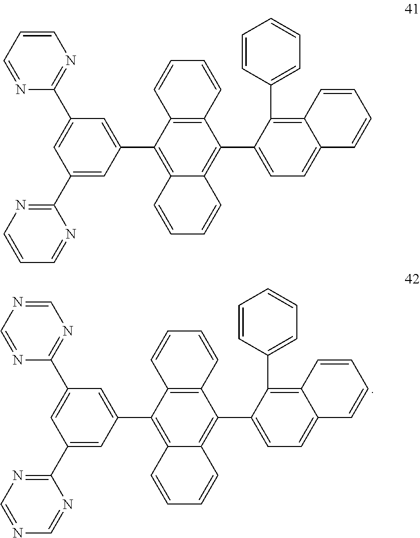

15. An electronic device including a display device providing images, the display device comprising:
a light emitting element that outputs a source light; and
a light control panel disposed on the light emitting element, wherein
the light control panel transmits the source light or converts a wavelength of the source light,
the light emitting element comprises:
a first electrode;
a second electrode facing the first electrode; and
at least one light emitting structure disposed between the first electrode and the second electrode,
the at least one light emitting structure comprises:
a hole transport region;
a light emitting layer, an electron transport region; and
an auxiliary layer disposed directly above or directly below the light emitting layer, and
the auxiliary layer comprises an anthracene compound represented by Formula 1: 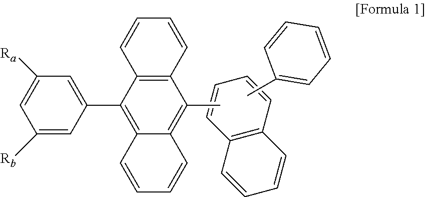
wherein in Formula 1,
Rₐ and R_{b} are each independently a group represented by Formula 2: 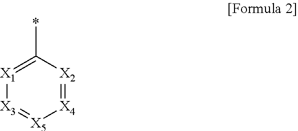
wherein in Formula 2,
X₁ to X₅ are each independently N or CH.

16. The electronic device of claim 15, wherein
the display device further comprises:
a first pixel area that emits red light;
a second pixel area that emits green light; and
a third pixel area that emits blue light,
the first to third pixel areas do not overlap each other in a plan view,
the light control panel comprises a light control layer comprising a quantum dot that converts a wavelength of the source light, and
the light control layer comprises:
a first light control part disposed to correspond to the first pixel area and comprising a first quantum dot that converts the wavelength of the source light;
a second light control part disposed to correspond to the second pixel area and comprising a second quantum dot that converts the wavelength of the source light; and
a third light control part disposed to correspond to the third pixel area.

17. The electronic device of claim 15, wherein
the hole transport region comprises:
a hole injection layer;
a hole transport layer; and
an electron blocking layer,
the hole injection layer, the hole transport layer, and the electron blocking layer are sequentially stacked in a thickness direction,
the electron transport region comprises:
a hole blocking layer;
an electron transport layer; and
an electron injection layer,
the hole blocking layer, the electron transport layer, and the electron injection layer are sequentially stacked in the thickness direction, and
the auxiliary layer is disposed directly between the light emitting layer and the hole blocking layer.

18. The electronic device of claim 15, wherein
the light emitting element comprises a host and a dopant, and
the auxiliary layer comprises the anthracene compound.

19. The electronic device of claim 15, wherein the auxiliary layer has a thickness in a range of about 10 Å to about 50 Å.

20. The electronic device of claim 15, wherein the anthracene compound is selected from Compound Group 1: 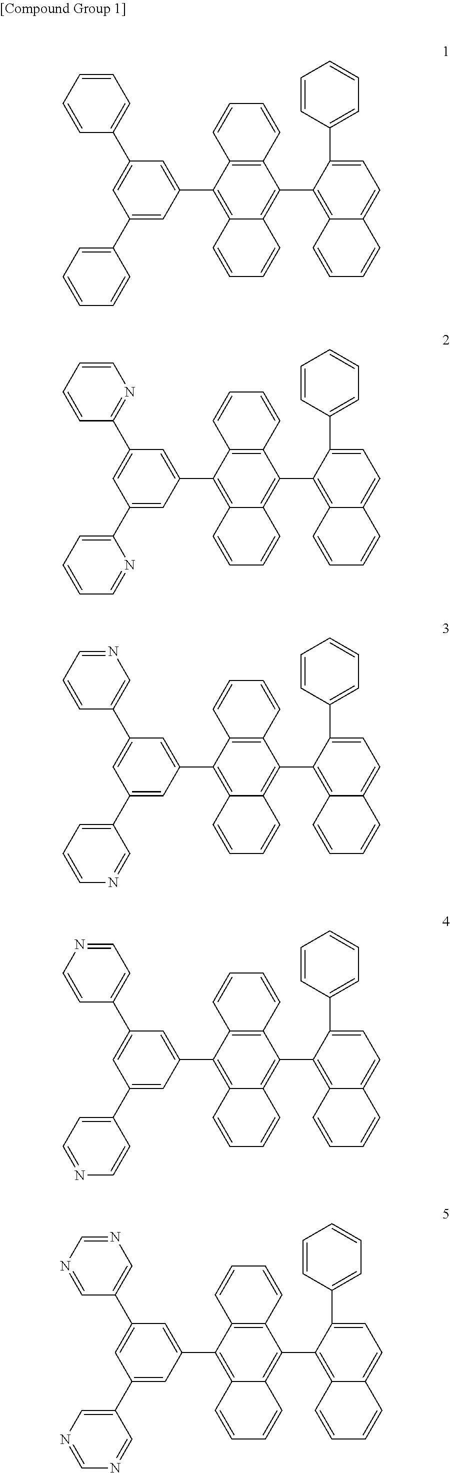 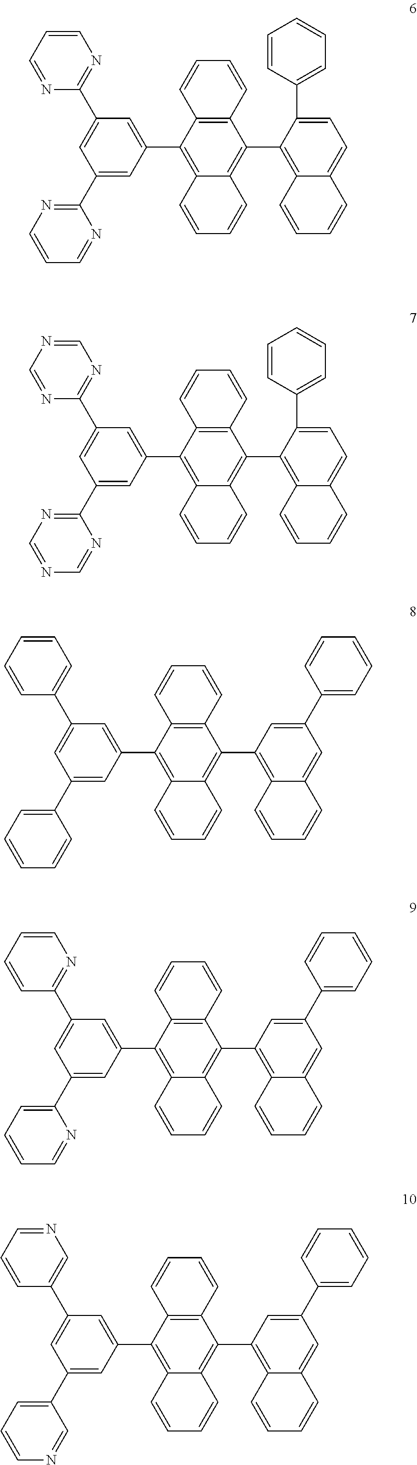 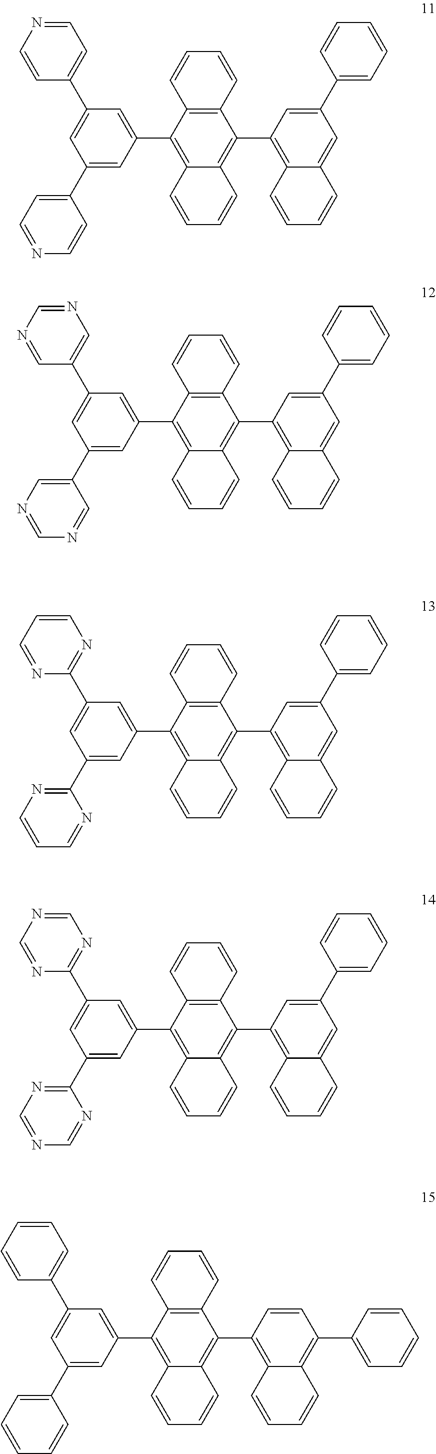 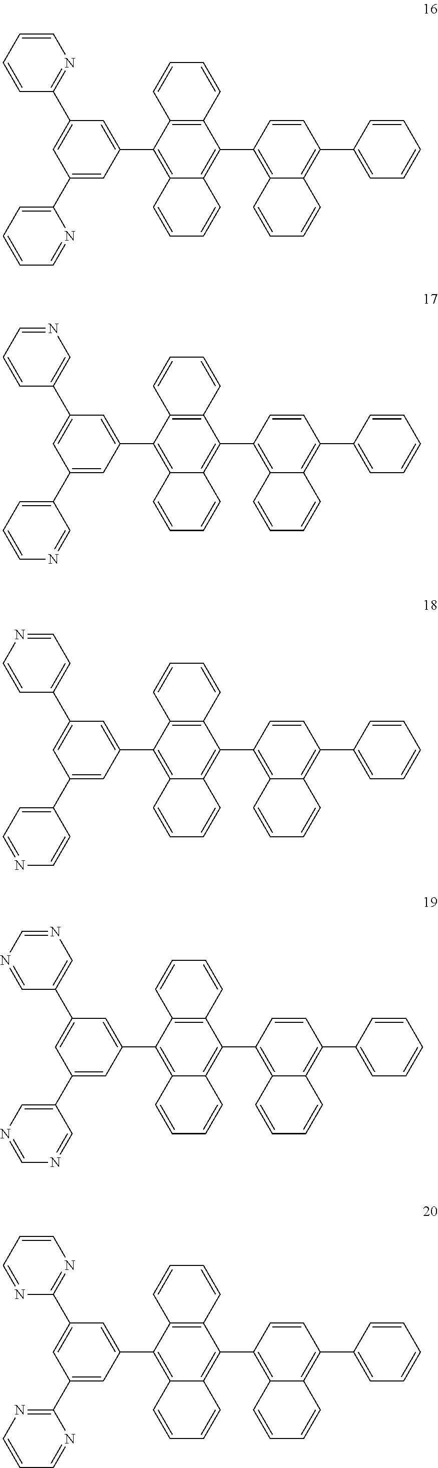 [SMILES: c1ccc(-c2ccc(-c3c4ccccc4c(-c4cc(-c5ccccn5)cc(-c5ccccn5)c4)c4ccccc34)c3ccccc23)cc1 ; c1ccc(-c2ccc(-c3c4ccccc4c(-c4cc(-c5cccnc5)cc(-c5cccnc5)c4)c4ccccc34)c3ccccc23)cc1 ; c1ccc(-c2ccc(-c3c4ccccc4c(-c4cc(-c5ccncc5)cc(-c5ccncc5)c4)c4ccccc34)c3ccccc23)cc1 ; c1ccc(-c2ccc(-c3c4ccccc4c(-c4cc(-c5cncnc5)cc(-c5cncnc5)c4)c4ccccc34)c3ccccc23)cc1 ; c1ccc(-c2ccc(-c3c4ccccc4c(-c4cc(-c5ncccn5)cc(-c5ncccn5)c4)c4ccccc34)c3ccccc23)cc1] 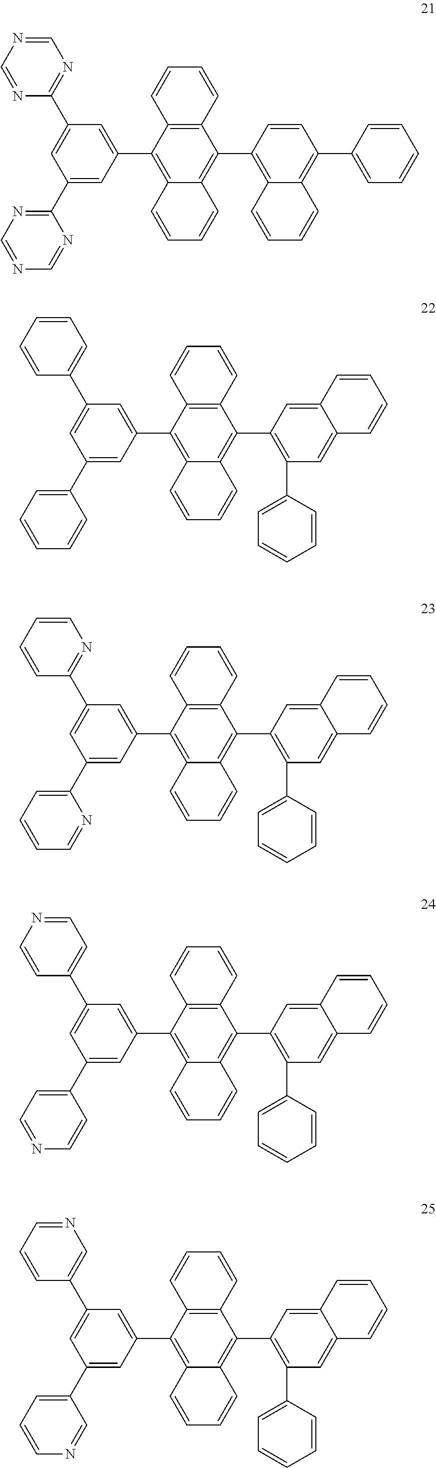 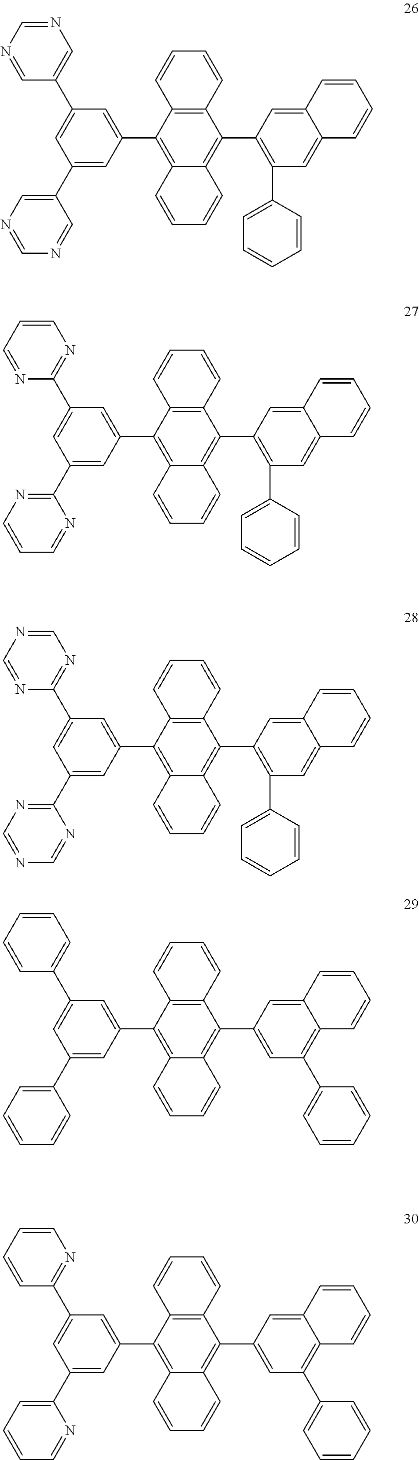 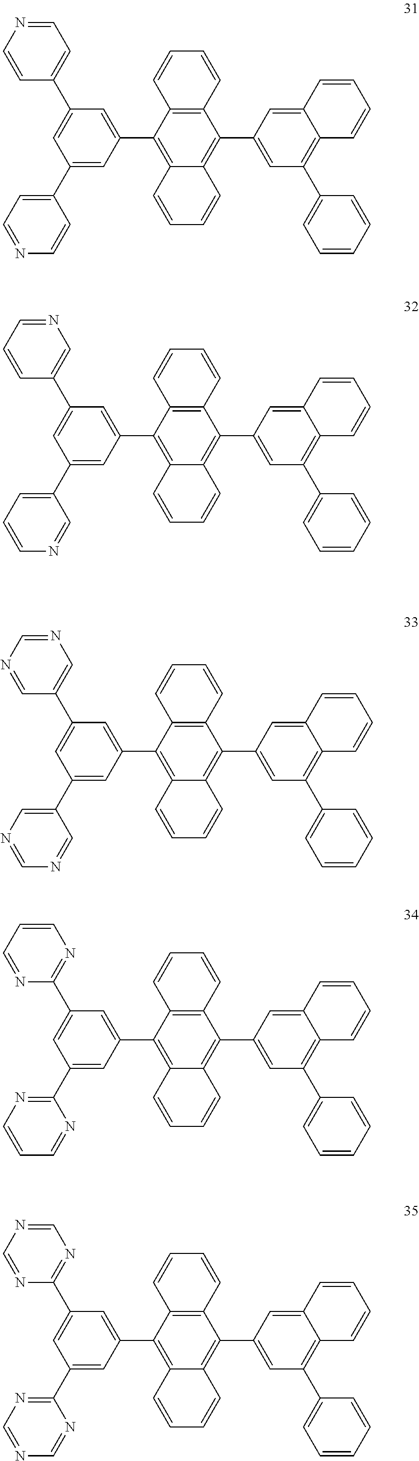 [SMILES: c1ccc(-c2cc(-c3c4ccccc4c(-c4cc(-c5ccncc5)cc(-c5ccncc5)c4)c4ccccc34)cc3ccccc23)cc1 ; c1ccc(-c2cc(-c3c4ccccc4c(-c4cc(-c5cccnc5)cc(-c5cccnc5)c4)c4ccccc34)cc3ccccc23)cc1 ; c1ccc(-c2cc(-c3c4ccccc4c(-c4cc(-c5cncnc5)cc(-c5cncnc5)c4)c4ccccc34)cc3ccccc23)cc1 ; c1ccc(-c2cc(-c3c4ccccc4c(-c4cc(-c5ncccn5)cc(-c5ncccn5)c4)c4ccccc34)cc3ccccc23)cc1 ; c1ccc(-c2cc(-c3c4ccccc4c(-c4cc(-c5ncncn5)cc(-c5ncncn5)c4)c4ccccc34)cc3ccccc23)cc1] 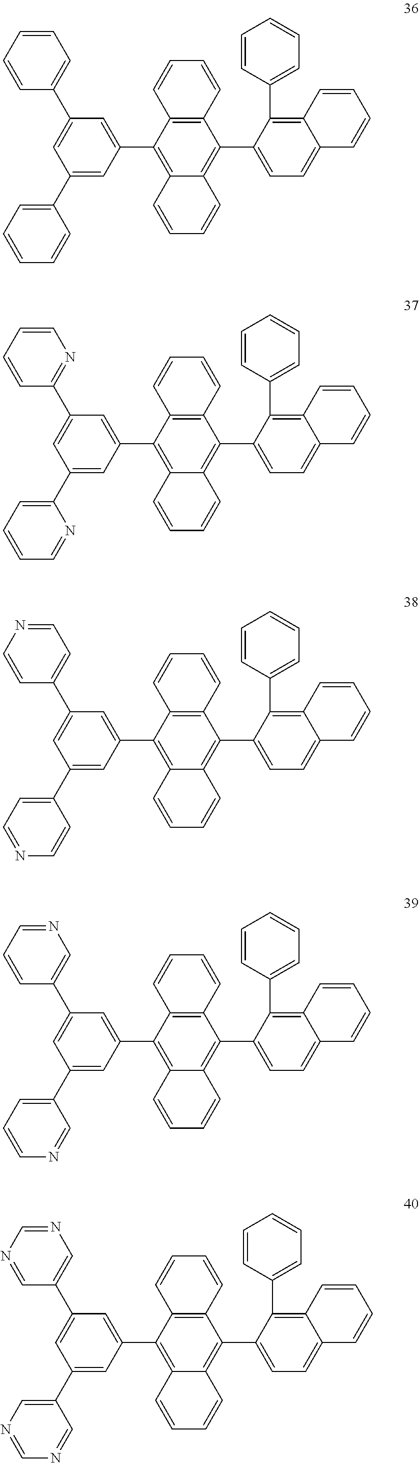 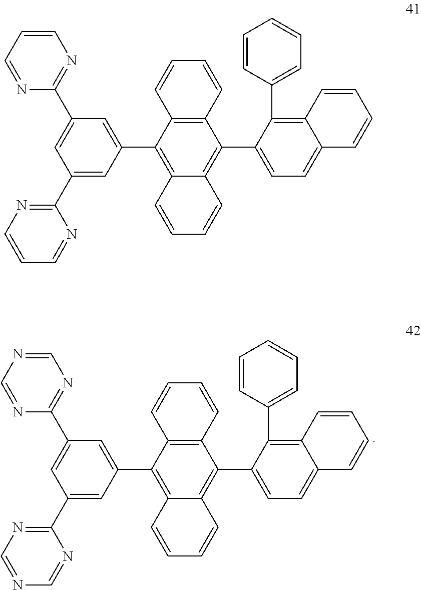 [SMILES: c1ccc(-c2c(-c3c4ccccc4c(-c4cc(-c5ncccn5)cc(-c5ncccn5)c4)c4ccccc34)ccc3ccccc23)cc1 ; c1ccc(-c2c(-c3c4ccccc4c(-c4cc(-c5ncncn5)cc(-c5ncncn5)c4)c4ccccc34)ccc3ccccc23)cc1]
